(19) United States
(12) Patent Application Publication
(10) Pub. No.: US 2011/0318689 A1
(43) Pub. Date: Dec. 29, 2011

(54) LIGHT-SENSITIVE LITHOGRAPHIC PRINTING PLATE MATERIAL

(76) Inventor: Akira Furukawa, Tokyo (JP)

(21) Appl. No.: 13/148,989

(22) PCT Filed: Feb. 12, 2010
(86) PCT No.: PCT/JP2010/052031

§ 371 Date: Aug. 11, 2011

(30) Foreign Application Priority Data
Feb. 13, 2009 (JP) 2009-032005
Dec. 8, 2009 (JP) 2009-278198

(51) Int. Cl. G03F 7/075

(52) U.S. Cl. 430/281.1

(57) ABSTRACT

An object of the present invention is to provide a light-sensitive lithographic printing plate material having high sensitivity, generating no background stain even when development is carried out by using a neutral developing solution having a pH of less than 9, or an alkali developing solution having a pH in the range of 9 to 12, generating no background stain even when the plate is allowed to stand after developing treatment or during printing for a long period of time, and having excellent in printing endurance and ink transfer property,

and it is accomplished by a light-sensitive lithographic printing plate material which comprises a support and a photo-curable light-sensitive layer formed thereon, said photo-curable light-sensitive layer contains a polymer synthesized by using at least a compound represented by the following mentioned general formula I:

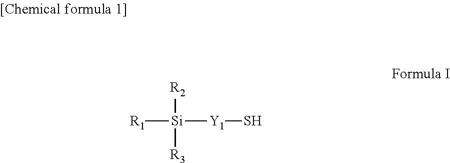

wherein R₁, R₂ and R₃ each independently represent an alkyl group or an alkoxy group each having 1 to 10 carbon atoms; provided that at least two of R₁, R₂ and R₃ represent alkoxy groups; and Y₁ represents an alkylene group having 1 to 10 carbon atoms,
   and having a polymerizable double bond group and at least one of a carboxyl group and a sulfonate group at a side chain.

### TECHNICAL FIELD

The present invention relates to a high sensitivity light-sensitive lithographic printing plate material improved in developability, printing property and plate preservation stability after processing the plate. In particular, it relates to a light-sensitive lithographic printing plate material in which a developing treatment is carried out with a neutral developing solution with a pH of less than 9 or an aqueous alkali solution having a pH in the range of 9 to 12.

### BACKGROUND ART

In recent years, it has been developed a computer to plate (CTP) technique in which, based on digital data prepared on a computer, an image is directly output on a printing plate without outputting on a film, and developments of various plate setters on which various lasers are mounted as an output machine and light-sensitive lithographic printing plate materials matching with them have been carried out very well. As an output laser in this case, there are at present two main streams, one of which utilizes a laser which emits light at a neighbor of 830 nm as a near-infrared light semiconductor laser, and the other utilizes a blue-purple colored semiconductor laser at a neighbor of 405 nm, and a CTP technique matching with these lasers has been investigated very well. As an important problem or demand which has brought into the public accompanying with spread of the CTP system, various points with regard to developing treatment can be mentioned. In the CTP with a usual system, after image-exposing a lithographic printing material with a laser, a non-image portion is dissolved out by an alkaline developing solution, washed with water and subjecting to gum-coating treatment to provide to a printing procedure. In particular, examples of a lithographic printing material suitable for the CTP with high sensitivity and excellent in printing endurance are disclosed in JP 2001-290271A (Patent Literature 1), JP 2002-278066A, JP 2003-43687A, etc., by using a polymer having a polymerizable double bond group at the side chain in a light-sensitive layer, and as a developing solution to be used for these materials, a high alkaline developing solution having a pH exceeding 12 has been used as disclosed in JP 2002-278083A (Patent Literature 2), JP 2002-278084A, JP 2002-278085A, etc.

When such a highly alkaline developing solution is used, there is a problem in lowering a pH due to absorption of carbon dioxide in the air, and accompanying with lowering in a pH, developability is also gradually lowered, so that to comply with the lowering thereof, it is necessary to supplement the developing solution frequently. As a result, a used amount of the highly alkaline developing solution is increased, and therefore, there are problem that storage and treatment of the highly alkaline developer waste liquor which causes as the result thereof requires much burden.

As an example of a light-sensitive lithographic printing plate material capable of treating in a system in which a pH of the developing solution is set to be 12 or less, there may be mentioned, for example, JP 2006-39177A (Patent Literature 3), JP 2006-64952A (Patent Literature 4), etc. These techniques are mainly intended to avoid background stain caused by development failure which became a problem when an alkaline developing solution having a pH of 12 or lower is used. It is essential for avoiding such a background stain to heighten developability of the light-sensitive lithographic printing plate material. However, accompanying with lowering the pH of the developing solution than 12, there are problems that developability at the non-image portion is generally lowered, and effects on developability due to fluctuation of a development temperature or a film thickness of the non-image portion, etc., are remarkable. This effect could not so remarkably be admitted when a high pH developing solution having a pH of 12 or higher was used, but when a developing solution having a pH lower than the above was used, marked change could be admitted in some cases. When developability is lowered, due to an effect of remaining film, background stain occurs. In particular, when the prepared plate was allowed to stand after preparation thereof and before applying to a printer, or when a printing machine was stopped during the printing for a long period of time and the plate was allowed to stand on a printer, etc., then, there was a problem that remarkable background stain occurred at the time of re-starting the printing. To avoid such problems concerning plate preservation, it has been required to improve hydrophilic property at the surface of the printing plate and maintain the same for a long period of time.

The problem of easily causing background stain due to plate preservation also markedly relates to the characteristics of the surface of the support to be used. In particular, as a support to be frequently used in the said field, there have been known an aluminum plate having a surface which had been subjected to surface roughening treatment and anodized, or a support having a hydrophilic layer containing colloidal silica at the surface thereof as herein below mentioned JP 2008-265297A (Patent Literature 5), etc. However, when a light-sensitive lithographic printing plate material is prepared by forming a photo-curable light-sensitive layer on the surface of these supports, since the support surface has extremely minute fine pores, there can be admitted a phenomenon in some cases that a material of said photo-curable light-sensitive layer is impregnated into such fine pores, and the material is stayed in the fine pores because the material cannot be dissolved out at the time of development. When such a film-remaining phenomenon occurred in the fine pores, the remained film could not be markedly admitted by naked eyes, but background stain easily occurred at the time of printing, in particular, there was a case when the plate was allowed to stand, the component of said light-sensitive layer was gradually diffused from the inside of the fine pores, whereby background stain was easily caused with a lapse of time.

On the other hand, as an attempt not to use the above-mentioned alkaline developing solution, for example, in JP 2008-265297A (Patent Literature 5), there is disclosed an example of a light-sensitive lithographic printing plate material which is capable of developing with water. According to this example, disclosed is a light-sensitive lithographic printing plate material which comprises a photo-curable light-sensitive layer containing a polymer having both of a sulfonic acid group and a phenyl group to which a vinyl group is bonded through a hetero ring at the side chain is provided on a support to which a specific hydrophilic layer is provided. In this case, developability is far low as compared with the case where the above-mentioned alkaline developing solution is used, so that there are problems that effects on developability due to fluctuation of the development temperature or film thickness at the non-image portion, etc., or effects on occurrence of background stain due to invasion into fine pores of the photo-curable light-sensitive layer and worsening of background stain after plate preservation, etc., are extremely markedly revealed.

These problems of background stain or background stain after plate preservation can be essentially avoided by dissolution property or developability of the photo-curable light-sensitive layer formed on the support surface. On the other hand, when developability is so heightened, particularly when developability is heightened so that it can be developed by water or an aqueous alkaline solution with a low pH, then, it causes bad effects on printing endurance at the time of printing, whereby even when background stain can be avoided, printing endurance is sacrificed so that it is extremely difficult to well-balance the both properties.

Moreover, in general, a gum-coating treatment is carried out on the surface of a printing plate in many cases after exposure and developing treatment at the time of preparing the plate. According to the gum treatment which has generally been carried out, occurrence of background stain relating to plate preservation can be improved with a certain extent, but it is not in a sufficient level, and it has further been desired to realize a printing plate which does not cause background stain by plate preservation without applying the gum treatment.

Also, in a light-sensitive lithographic printing plate material in which a developing treatment is carried out with a neutral developing solution having a pH of less than 9 or an aqueous alkaline solution having a pH in the range of 9 to 12, in addition to the above-mentioned problems concerning plate preservation or background stain, there are problems that due to weakness in abrasion resistance at the image portion, when the printing is continued, fine lines become thinner, printing endurance of fine dot image with a dot area of 5% or less is poor, and accompanying with a number of printed sheets, dot area is gradually decreased on the printed material. Also, with regard to ink transfer property, accompanying with a number of printed sheets, the image portion on the printing plate is gradually abraded and a density of the printed material is lowered. Such problems are caused by the reasons that abrasion resistance and adhesiveness of the light-sensitive layer after photocuring are essentially insufficient. To improve abrasion resistance, it is necessary to improve resin components which constitute the photo-curable light-sensitive layer, and with regard to improvement of adhesiveness, the conventional photo-curable light-sensitive layer involved the problem that its adhesiveness is markedly affected by the properties of the adjacent hydrophilic layer so that essential improvement has been desired. In particular, it has been desired to solve the problems while maintaining the characteristics that the material can be developed with an alkali developing solution having a pH range of 9 to 12 or a neutral developing solution having a pH of less than 9.

On the other hand, in JP 2001-228614A (Patent Literature 6), there is disclosed that a lithographic printing plate raw plate can be provided, which is excellent in printing endurance and particularly excellent in endurance to a plate cleaner in a lithographic printing material which comprises an alkali soluble polyurethane binder such as polydimethylsiloxane, etc., containing an organopolysiloxane group. It is certainly improved in printing endurance by incorporation of a polysiloxane group, but a tendency of lowering alkali developability is remarkable due to the incorporation. This was not a system showing good developability particularly for the light-sensitive lithographic printing plate material which is capable of developing with an alkaline developing solution having a pH range of 9 to 12 or a neutral developing solution having a pH of less than 9 objected according to the present invention.
[Patent Literature 1] JP 2001-290271A
[Patent Literature 2] JP 2002-278083A
[Patent Literature 3] JP 2006-39177A
[Patent Literature 4] JP 2006-64952A
[Patent Literature 5] JP 2008-265297A
[Patent Literature 6] JP 2001-228614A

### DISCLOSURE OF THE INVENTION

### Problems to be Solved by the Invention

An object of the present invention is to provide a light-sensitive lithographic printing plate material which has high sensitivity, causing no background stain even when a developing treatment is carried out with a neutral developing solution having a pH of less than 9 or an alkali developing solution having a pH range of 9 to 12, causing no background stain even when the plate was allowed to stand for a long period of time after developing treatment or during printing even when no gum-coating treatment is carried out, and providing excellent printing endurance and ink transfer property.

### Means to Solve the Problems

The problems of the present invention can be basically solved by the following method. That is, in the photo-curable light-sensitive layer on the support, the light-sensitive lithographic printing plate material contains a polymer synthesize by using at least a compound represented by the following-mentioned general formula I and having a polymerizable double bond group and at least one of a carboxyl group and a sulfonate group at the side chain.

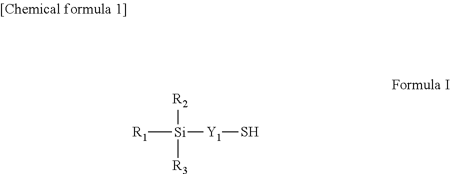

In the formula I, R₁, R₂ and R₃ each independently represent an alkyl group or an alkoxy group having 1 to 10 carbon atoms, preferably 1 to 6 carbon atoms, and more preferably 1 to 4 carbon atoms, provided that at least two of R₁, R₂ and R₃ represent alkoxy groups. Y₁ represents an alkylene group having 1 to 10 carbon atoms, preferably 1 to 6 carbon atoms, and more preferably 1 to 4 carbon atoms.

### Effects of the Invention

According to the present invention, it can be obtained a light-sensitive lithographic printing plate material having high sensitivity, causing no background stain even when a developing treatment is carried out with a neutral developing solution having a pH of less than 9 or an alkali developing solution having a pH range of 9 to 12, causing no background stain even when the plate was allowed to stand for a long period of time after developing treatment or during printing even when no gum treatment is carried out, and providing excellent printing endurance and ink transfer property.

### BEST MODE TO CARRY OUT THE INVENTION

A general explanation concerning a polymer synthesized by using a compound shown by the general formula I is firstly carried out. That is, the compound shown by the general formula I has a mercapto group in the molecule, so that it acts as the so-called chain-transfer agent which is well known in a radical polymerization reaction. A hydrogen atom is withdrawn from the mercapto group by a radical which is an active intermediate formed in the radical polymerization reaction to generate a sulfur radical. It has been well known that by adding the sulfur radical to the monomer, a radical polymerization is re-started and a polymer in which the sulfur atom is bonded to the terminal is formed. However, the characteristic feature of the compound represented by the general formula I to be used in the present invention resides in having a silicon atom to which at least two alkoxy groups are bonded simultaneously in the structure. The alkoxy groups bonded to the silicon atom are easily hydrolyzed in the presence of water to form a hydroxyl group(s) in some cases. Or else, the hydroxyl groups formed by the hydrolysis are condensed to each other to form a —Si—O—Si— bond in some cases. From such a situation, when a radical polymerization is carried out by using the compound represented by the general formula I, the following two polymers can be obtained as a polymer having a polymerizable double bond group, and a carboxyl group or a sulfonate group at the side chain.

The first case is a case of a polymer having a group represented by the following general formula II at the end of the main chain of the polymer. In the present invention, the inventors have found that the light-sensitive lithographic printing plate material specifically comprising the following constitution can solve the problems to be solved by the present invention. That is, it is a light-sensitive lithographic printing plate material which contains a polymer having a group represented by the following general formula II at the end of the main chain and having a polymerizable double bond group, and a carboxyl group or a sulfonate group at the side chain in the photo-curable light-sensitive layer on the support.

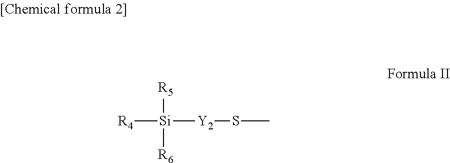

In the general formula II, R₄, R₅ and R₆ each independently represent a hydroxyl group, an alkyl group or an alkoxy group each having 1 to 10 carbon atoms, preferably having 1 to 6 carbon atoms, further preferably having 1 to 4 carbon atoms, provided that at least two of R₄, R₅ and R₆ represent hydroxyl groups or alkoxy groups. Y₂ represents an alkylene group having 1 to 10 carbon atoms, preferably having 1 to 6 carbon atoms, further preferably having 1 to 4 carbon atoms.

Another case is a case where the groups represented by the above-mentioned general formula II are condensed by dehydration to form a —Si—O—Si— bond, whereby the terminal groups of the polymers are bonded to form a polysiloxane. The inventors have found that the light-sensitive lithographic printing plate material comprising the following constitution can solve the problems to be solved by the present invention in this case. That is, it is a light-sensitive lithographic printing plate material comprising a photo-curable light-sensitive layer on a support, which contains a polymer in which a unit having a polyorganosiloxane structure, and a unit having a polymerizable double bond group, and a carboxyl group or a sulfonate group at the side chain being bonded through a sulfur atom.

First, the polymer having the group represented by the above-mentioned general formula II at the end of the main chain, and having a polymerizable double bond group, and a carboxyl group or a sulfonate group at the side chain is explained.

As one of the methods to introduce various functional groups at the end of the main chain of the polymer, it has widely been used a method in which a radical polymerization of a monomer(s) (M) in the presence of various kinds of a mercapto compound (R—SH) as shown in the following scheme I.

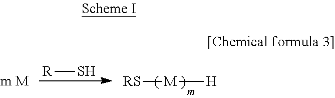

In the above-mentioned scheme I, m represents an added molar number of the monomer M, and it shows that the RS group binds to the α terminal of the polymer with a polymerization degree of m and the hydrogen atom binds to the ω terminal of the same by the polymerization. Also, R in the formula represents —Y₁—Si(R₁)(R₂)(R₃) of the above-mentioned formula I, and m represents an integer in the range of 2 to 1000, more preferably an integer in the range of 10 to 100.

There is a preferred range in the molar ratio of the monomer M and the above-mentioned the mercapto compound to be used, and the preferred amount of the mercapto compound to be added to the monomer M is preferably in the range of 0.5 to 60 mol % as described below, more preferably in the range of 1 to 40 mol %. With regard to the polymerization conditions, various conditions such as a kind and an amount to be added of the polymerization initiator, a polymerization temperature, a monomer concentration, etc., are not particularly limited and can be selected from the range well known in the art.

By introducing various functional groups into the group R to which a mercapto group binds in the above formula, a polymer in which the group RS— is introduced into the α terminal of the polymer main chain having various functional groups, and the hydrogen atom (—H) is introduced into the ω terminal of the same is synthesized. In the present invention, as the mercapto compound (R—SH) to be used, the mercapto compound represented by the above-mentioned formula I is used, and various monomers mentioned below are polymerized in the presence of the above compound to obtain an objective polymer of the present invention.

Particularly preferred examples of the compound represented by the general formula I may be mentioned 3-mercaptopropyl(dimethoxy)methylsilane, 3-mercaptopropyltrimethoxysilane, 3-mercaptopropyl(diethoxy)methylsilane, 3-mercaptopropyltriethoxysilane, etc.

To obtain said polymer of the present invention, in the presence of the compound represented by the above-mentioned general formula I, a monomer which is to provide a polymerizable double bond group at the side chain and a monomer having a carboxyl group or a sulfonate group are copolymerized to obtain an objective polymer.

The monomer having a carboxyl group herein used is firstly explained. The monomer having a carboxyl group which can be used in the present invention may be specifically mentioned and preferably used an acrylic acid, methacrylic acid, itaconic acid, crotonic acid, maleic acid, partially esterified maleic acid, and various kinds of carboxyl group-containing monomers shown by the following chemical formulae.

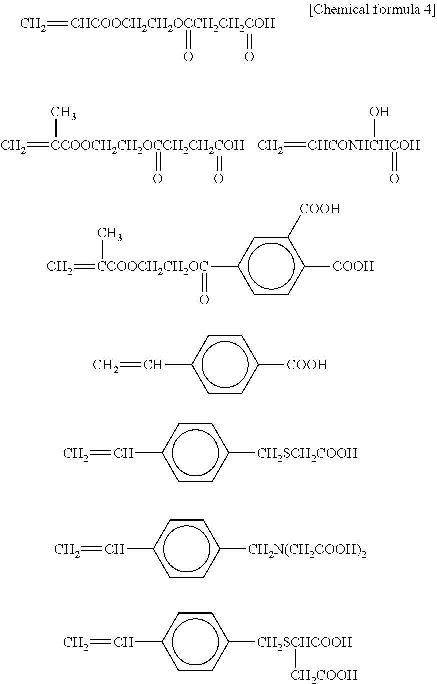

Next, the monomer having a sulfonate group which is another element for constituting the polymer of the present invention is explained. Examples of such a monomer having a sulfonate group may be mentioned an alkali metal salt, amine salt and quaternary ammonium salt of vinylsulfonic acid, an alkali metal salt, amine salt and quaternary ammonium salt of styrenesulfonic acid, an alkali metal salt, amine salt and quaternary ammonium salt of acrylamide-2-methylpropanesulfonic acid, an alkali metal salt, amine salt and quaternary ammonium salt of allylsulfonic acid, an alkali metal salt, amine salt and quaternary ammonium salt of methallylsulfonic acid, an alkali metal salt, amine salt and quaternary ammonium salt of methacrylic acid 3-sulfopropyl ester, etc., as preferred examples. The alkali metal salt herein mentioned means a sodium salt, potassium salt and lithium salt, the amine salt means a salt formed by amines such as ammonia, triethylamine, tributylamine, monoethanolamine, diethanolamine, triethanolamine, dimethylaminoethanol, diethylaminoethanol, methylaminoethanol, ethylaminoethanol, n-butyldiethanolamine, t-butyldiethanolamine, etc., as an amine, and the quaternary ammonium salt means a salt formed by using tetramethyl ammonium hydroxide, tetraethyl ammonium hydroxide, tetrapropyl ammonium hydroxide, tetrabutyl ammonium hydroxide, choline, phenyltrimethyl ammonium hydroxide, or benzyltrimethyl ammonium hydroxide.

Next, the monomer for providing a polymerizable double bond group to the side chain which is to form the polymer of the present invention is explained. The monomer herein mentioned may be mentioned two types of monomers, one of which is a monomer which gives the polymer having a polymerizable double bond group at the side chain by polymerizing itself according to the above-mentioned scheme I, and the other is a monomer in which at the step of polymerizing the monomers by the above-mentioned scheme I, no polymerizable double bond group is yet introduced into the side chain, and it is used to introduce the polymerizable double bond group into the polymer obtained by the polymerization according to the above-mentioned scheme I.

Examples of the former, i.e., the monomer which gives the polymer having a polymerizable double bond group at the side chain by polymerizing itself, there may be mentioned, for example, a (meth)acrylic acid allyl ester. In the case of this monomer, there exist two polymerizable double bond groups in the molecule, and there is remarkable difference in polymerizability between that of the (meth)acryloyl group and that of the other allyl group. The polymerizability of the former is markedly high so that polymerization predominantly proceed with the (meth)acryloyl portion, so that a polymer in which an allyl group is pendanted at the side chain can be formed. Accordingly, the obtained polymer becomes a polymer in which an allyl group which is a polymerizable double bond group is bound to the side chain. Other examples of the monomer having two kinds of polymerizable double bond groups having markedly different polymerizability in the molecule may be mentioned the monomers shown below. In these examples, all of which having a (meth)acryloyl group or a styryl group as a higher polymerizability group, and having a vinyl acetate ester group, a vinyl ether group or an allyl group as a lower polymerizability group are exemplified. Of these examples, the vinyl acetate ester group is a group having extremely high polymerizability when it is present alone, but in the copresence of a (meth)acryloyl group or a styryl group, polymerization of the vinyl acetate ester group is hardly caused until the latter is consumed by polymerization so that this property is utilized. Accordingly, when the polymer of the present invention is to be synthesized by using the monomer having two kinds of polymerizable double bond groups in the molecule, it is preferred to obtain a polymer at the stage at which the polymerizable double bond group with a lower polymerizability is not yet polymerized by stopping the polymerization during the same without completing the polymerization.

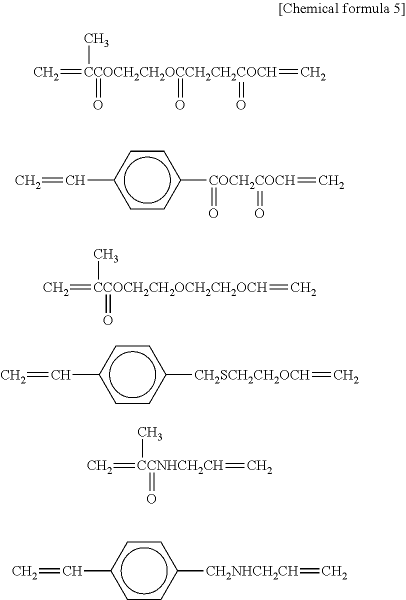

Next, a monomer (hereinafter referred to “a precursor monomer”) to be used for introducing a polymerizable double bond group into the side chain subsequent to the polymerization of the scheme I is explained.

The monomer which can be used as a precursor monomer is a monomer having both of the polymerizable double bond group and further other reactive group, and as the said reactive group, there may be mentioned a hydroxyl group, carboxyl group, amino group, mercapto group, epoxy(glycidyl) group, isocyanate group, haloalkyl group, acid anhydride group, amino group and other well known reactive groups. Examples of the compound which can be used as the precursor monomer may be mentioned hydroxyethyl(meth)acrylate, hydroxypropyl(meth)acrylate, acrylic acid, methacrylic acid, crotonic acid, itaconic acid, glycidyl(meth)acrylate, mercaptomethylstyrene, aminostyrene, chloromethylstyrene, chloroethylvinyl ether, maleic anhydride, dimethylaminoethyl(meth)acrylate, diethylaminoethyl(meth)acrylate, etc.

As the compound which can be particularly preferably used as the above-mentioned precursor monomer, there may be mentioned a compound in which a mercapto group is bonded through the heterocyclic ring group represented by the following general formula III.

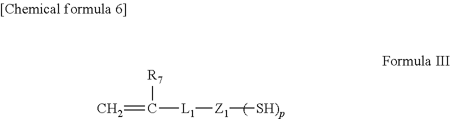

wherein L₁ represents a linking group, R₇ represents a hydrogen atom or a methyl group. p represents 1 or 2. Z₁ represents a heterocyclic ring group.

As the linking group of L₁, there may be mentioned an oxygen atom, sulfur atom, alkylene group, alkenylene group, arylene group, —N(Rₐ)—, —C(O)—O—, —C(R_{b})═N—, —C(O)—, sulfonyl group and a linking group in which the above are complexed. Here, Rₐ and R_{b} are each represents a hydrogen atom, alkyl group, aryl group, etc. Further, the above-mentioned linking group may have a substituent(s) such as an alkyl group, aryl group, halogen atom, etc. Moreover, a carbon number of the alkylene group and the alkenylene group possessed by the linking group L₁ of the general formula III are preferably in the range of 1 to 20, and a carbon number of the arylene group is preferably in the range of 6 to 20.

As the heterocyclic ring group shown by the above-mentioned Z₁, there may be mentioned a nitrogen-containing heterocyclic ring such as a pyrrol ring, pyrazole ring, imidazole ring, triazole ring, tetrazole ring, isoxazole ring, oxazole ring, oxadiazole ring, isothiazole ring, thiazole ring, thiadiazole ring, thiatriazole ring, indole ring, indazole ring, benzimidazole ring, benzotriazole ring, benzoxazole ring, benzthiazole ring, benzselenazole ring, benzothiadiazole ring, pyridine ring, pyridazine ring, pyrimidine ring, pyrazine ring, triazine ring, quinoline ring, quinoxaline ring, etc., a furan ring, a thiophen ring, etc., and a substituent(s) may be bound to these heterocyclic rings. Examples of the compound represented by the general formula III are mentioned below, but the present invention is not limited to these examples.

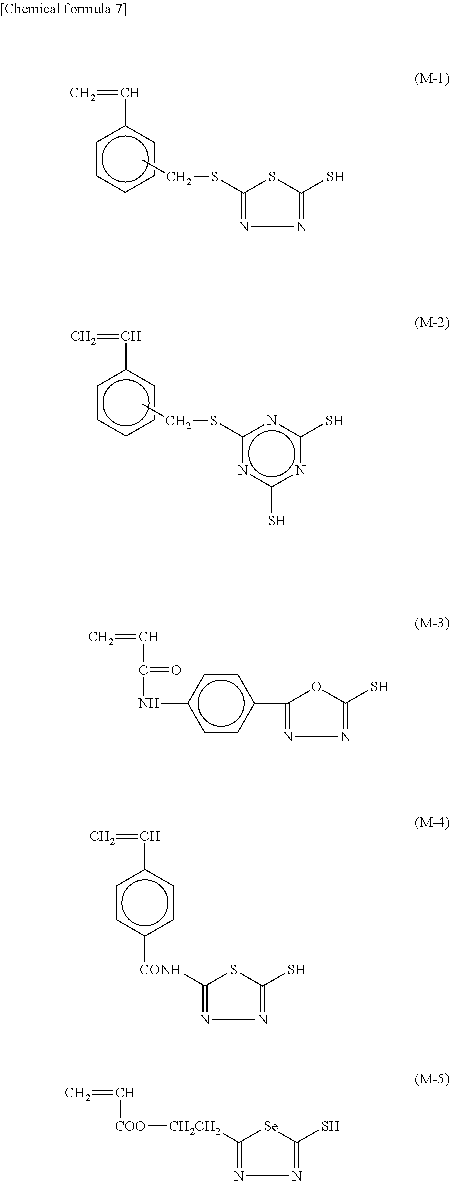

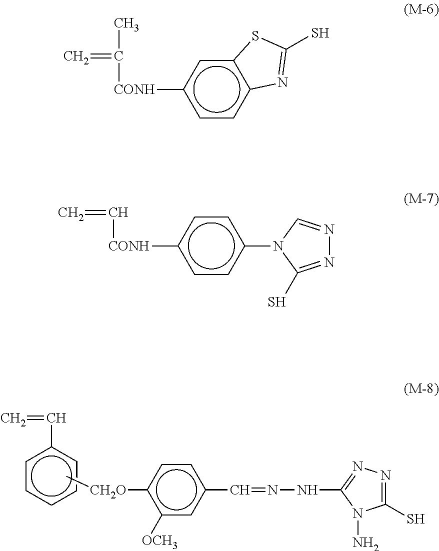

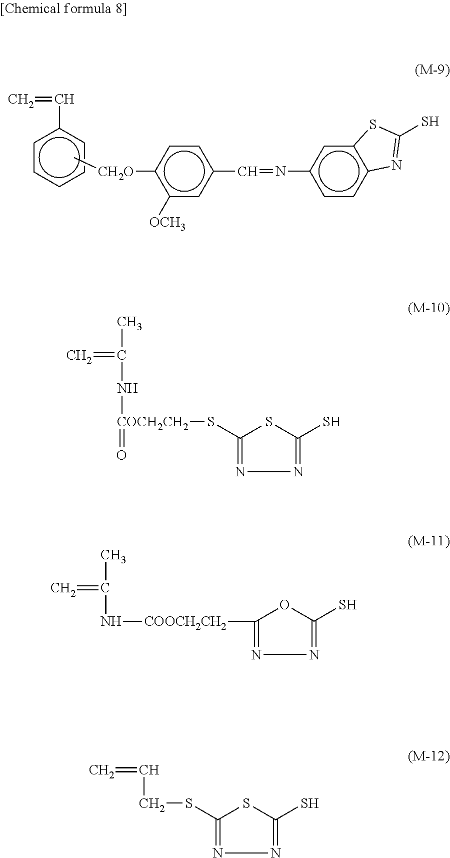

As a characteristic feature of the mercapto group bound to the heterocyclic ring group as mentioned above, there may be mentioned a characteristic that it has higher acidity as compared to the mercapto group bound to an alkyl group. Such a mercapto group bound to the heterocyclic ring group can be neutralized by addition of, for example, an organic amine, etc., as a relatively weak base, etc., to form a salt in some cases. The function of the mercapto group as a chain transfer group is lowered by forming a salt with an organic amine, etc., so that the above-mentioned compound can form a precursor polymer before introducing the polymerizable double bond group at the side chain by carrying out polymerization (scheme I) using a usual radical polymerization initiator. Accordingly, in the presence of the mercapto compound of the above-mentioned general formula I (the mercapto compound of the general formula I does not form a salt in the presence of a weak base such as an organic amine, etc., and has high chain transferability), when polymerization is carried out by using a salt of the compound having a mercapto group through the above-mentioned, then the above-mentioned precursor polymer can be formed.

As a compound which can be preferably used as the above-mentioned organic amine, there may be preferably used compounds such as ammonia, triethylamine, monoethanolamine, diethanolamine, triethanolamine, dimethylaminoethanol, diethylaminoethanol, methylaminoethanol, ethylaminoethanol, n-butyldiethanol amine, t-butyl-diethanol amine, etc.

By adding a compound having a polymerizable double bond group which can bind to the above-mentioned precursor monomer to a precursor polymer, a polymerizable double bond group can be introduced into the side chain of the precursor polymer. Such a compound having the polymerizable double bond group may be used various kinds of compounds already known as a monomer having a reactive group. As the reactive group, there may be mentioned a hydroxyl group, a carboxyl group, an amino group, a mercapto group, an epoxy(glycidyl) group, a haloalkyl group, an acid anhydride group and other known reactive groups. Preferred examples of the compound which can be used as the monomer having a reactive group, there may be mentioned hydroxyethyl(meth)acrylate, hydroxypropyl(meth)acrylate, acrylic acid, methacrylic acid, crotonic acid, itaconic acid, glycidyl(meth)acrylate, chloromethyl-styrene, chloroethylvinyl ether, maleic anhydride, dimethylaminoethyl(meth)acrylate, diethylaminoethyl(meth)acrylate, etc.

When a compound in which a mercapto group is bound through the heterocyclic ring group represented by the general formula III previously mentioned is used as a precursor monomer, chloromethylstyrene can be mentioned as the most preferred monomer having said reactive group. The reaction generated by the combination of the mercapto group and chloromethylstyrene can proceed under mild conditions with high yield so that it can be extremely preferably used.

Or else, as the reverse combination to the above, as shown in the below-mentioned Synthetic examples, a precursor polymer is synthesized by using chloromethylstyrene as a precursor monomer, then, by adding mercaptomethylstyrene or a compound represented by the above-mentioned formula III as a monomer having a reactive group to introduce the polymerizable double bond group into the side chain of the precursor polymer to react them to obtain the polymer of the present invention with high yield, whereby the method can be preferably used.

When a vinyl group bonded to the phenyl group is used as a polymerizable double bond group to be introduced into the side chain of the polymer of the present invention, it is particularly preferred since the reactivity of said vinyl group is high. Moreover, it is particularly preferred that the vinyl group is bonded to the phenyl group which is linked through a heterocyclic ring. In this case, it is characteristics that it has good photocurability, and showing no curing inhibition by oxygen, further is stable with a lapse of time, and shows good photocurability without applying any heat treatment after photo-irradiation. Preferred examples of such a polymerizable double bond group to be introduced into the side chain are shown below with the general formula IV.

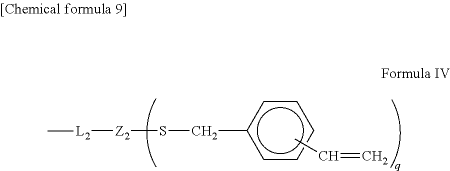

L₂ and Z₂ in the general formula IV are the same with L₁ and Z₁ in the general formula III mentioned above, respectively. q represents 1 or 2.

Specific examples of the polymerizable double bond group shown by the general formula IV are mentioned below, but the invention is not limited by these examples.

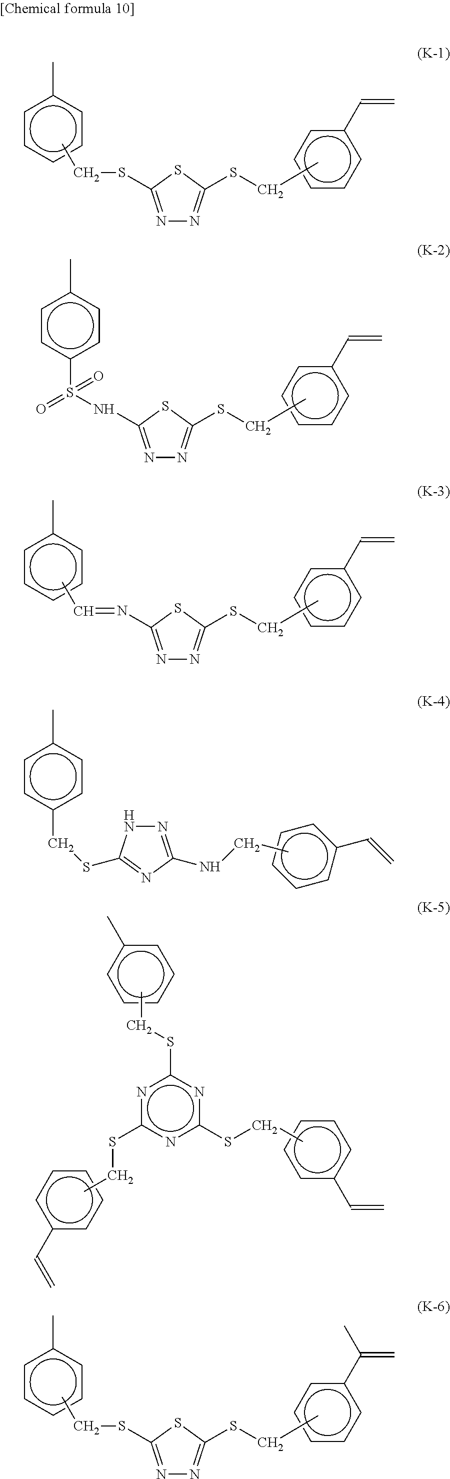

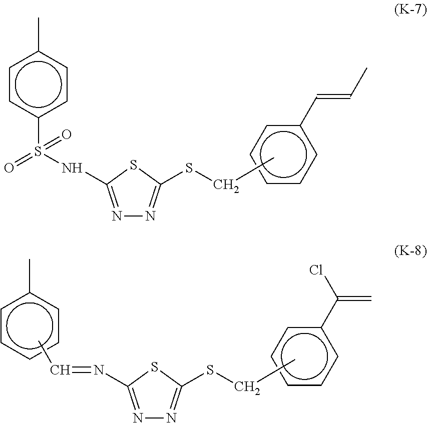

When the monomer having a carboxyl group explained above is to be used, the polymer of the present invention which is soluble in an alkali developing solution having a pH in the range of 9 to 12 can be obtained. Or else, when the above-mentioned monomer having a sulfonate group is to be used, the polymer of the present invention which is soluble in a neutral developing solution having a pH of less than 9 can be obtained.

In the polymer of the present invention, other than the above-mentioned monomers, there may be used as a copolymerizable monomer, for example, styrene derivatives such as styrene, 4-methylstyrene, 4-acetoxystyrene, 4-methoxystyrene, etc.; various alkyl(meth)acrylates such as methyl(meth)acrylate, ethyl(meth)acrylate, butyl(meth)acrylate, etc.; monomers having a nitrogen-containing heterocyclic ring such as 4-vinylpyridine, 2-vinylpyridine, N-vinylimidazole, N-vinylcarbazole, etc.; or as a monomer having a quaternary ammonium salt group, there may be used a quaternarized material by methyl chloride of 4-vinylbenzyltrimethyl ammonium chloride, (meth)-acryloyloxyethyltrimethyl ammonium chloride, dimethylaminopropylacrylamide; a quaternarized material by methyl chloride of N-vinylimidazole; 4-vinylbenzyl-pyridinium chloride, etc.; or (meth)acrylonitrile, (meth)acrylamide derivatives such as (meth)acrylamide, dimethyl(meth)acrylamide, diethyl(meth)acrylamide, N-isopropyl(meth)acrylamide, diacetone(meth)acrylamide, N-methylol(meth)acrylamide, N-methoxyethyl(meth)acrylamide, 4-hydroxyphenyl(meth)acrylamide, etc.; further vinyl esters such as phenylmaleimide, hydroxyphenylmaleimide, vinyl acetate, chlorovinyl acetate, vinyl propionate, vinyl butyrate, vinyl stearate, vinyl benzoate, etc.; and vinyl ethers such as methylvinyl ether, butylvinyl ether, etc.; and other various monomers such as N-vinylpyrrolidone, acryloylmorpholine, tetrahydrofurfuryl methacrylate, vinyl chloride, vinylidene chloride, allyl alcohol, vinyltrimethoxysilane, etc.; optionally as a copolymerizable monomer.

In this case, as the ratio of the carboxyl group-containing monomer or the sulfonate group-containing monomer in the copolymer composition, these monomers are preferably contained in an amount of 20% by weight or more and 70% by weight or less, more preferably 30% by weight to 70% by weight, further preferably 35% by weight to 70% by weight based on the total composition as 100% by weight. If they are less than the above ratio, there is a case where the copolymer does not dissolve in an alkali developing solution having a pH in the range of 9 to 12 or in a neutral developing solution having a pH of less than 9. Moreover, when the ratio of these monomers contained in the copolymer exceeds 60% by weight, there is a case where sufficient printing endurance cannot be obtained.

Examples of the polymer having a group represented by the above-mentioned formula II at the end of the main chain of the polymer, and having a polymerizable double bond group and a carboxyl group at the side chain preferably used in the present invention are as mentioned below. The numerals in the FIGURE represent a ratio of the copolymer composition (weight ratio). A terminal group structure is shown at the left end of the chemical formula of the FIGURE, and in the terminal group structure, the alkoxy group bonded to the silicon atom includes the case where it is turned into a hydroxyl group by hydrolysis reaction.

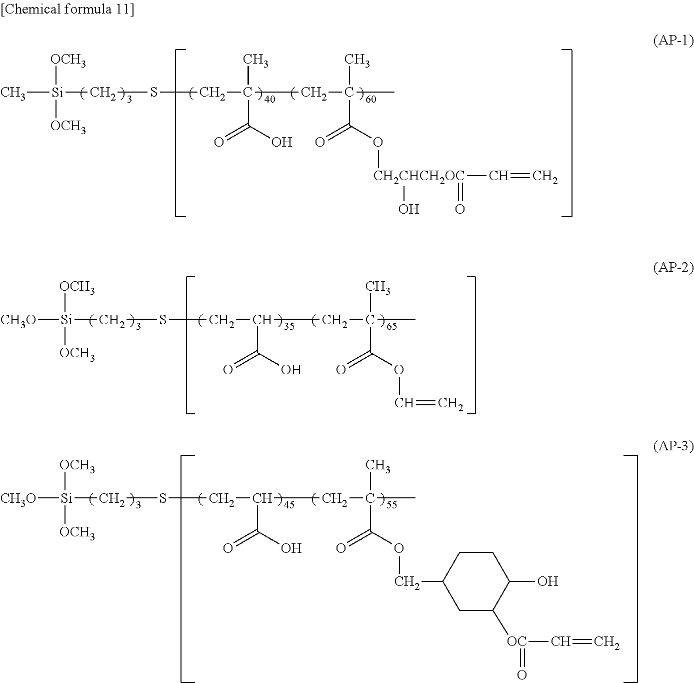

As the most preferred examples of the polymer having a group represented by the above-mentioned formula II at the end of the main chain, and a polymerizable double bond group and a carboxyl group at the side chain, there may be mentioned a polymer in which the polymerizable double bond group is a phenyl group to which a vinyl group is bonded through a hetero ring as disclosed in, for example, JP 2001-290271A. Examples of such a polymer are shown below. The numerals in the FIGURE represent a ratio of the copolymer composition (weight ratio).

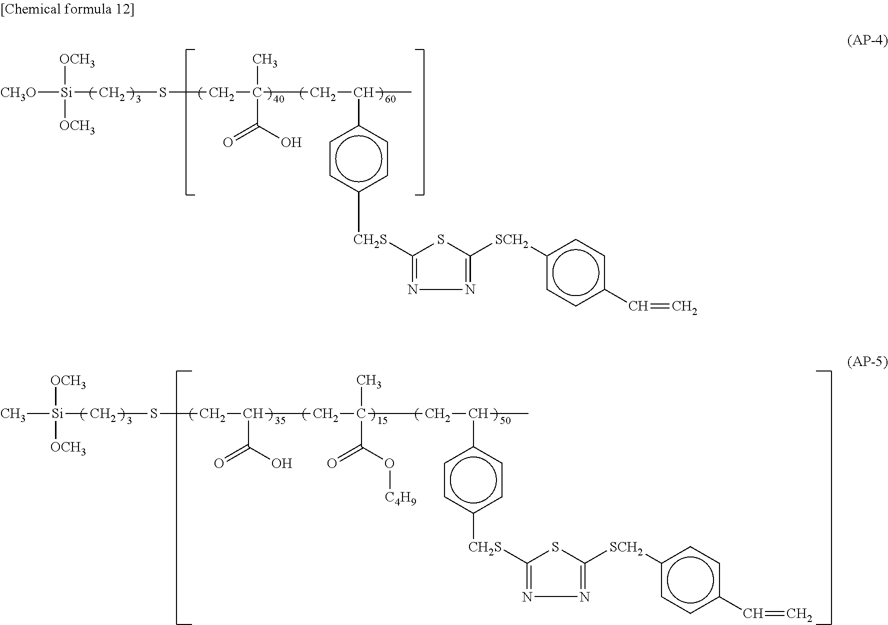

Examples of the polymer having the group represented by the above-mentioned formula II at the end of the main chain of the polymer and having a polymerizable double bond group and a sulfonate group at the side chain which can be preferably used in the present invention are shown below. The numerals in the FIGURE represent a ratio of the copolymer composition (weight ratio).

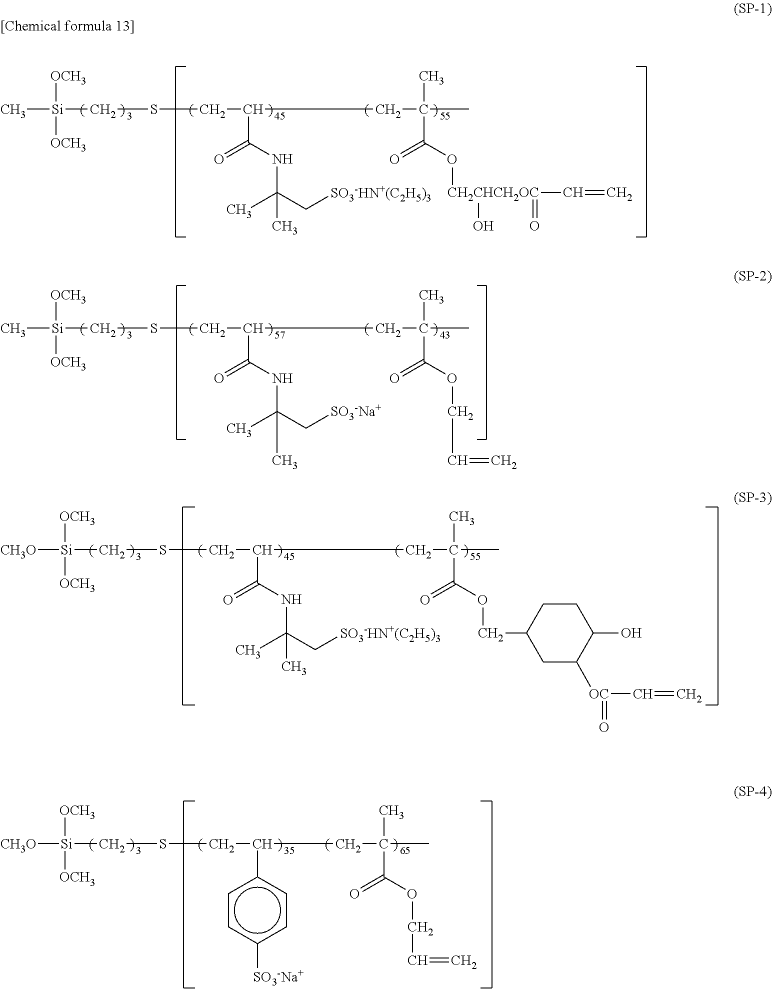

As the most preferred examples of the polymer having the group represented by the above-mentioned formula II at the end of the main chain of the polymer and a polymerizable double bond group and a sulfonate group at the side chain, there may be mentioned a polymer having a sulfonate group and a phenyl group to which a vinyl group is bonded through a hetero ring as described in, for example, JP 2008-265297A. The most preferred examples of said binder polymer are mentioned below. The numerals in the FIGURE represent a ratio of the copolymer composition (weight ratio).

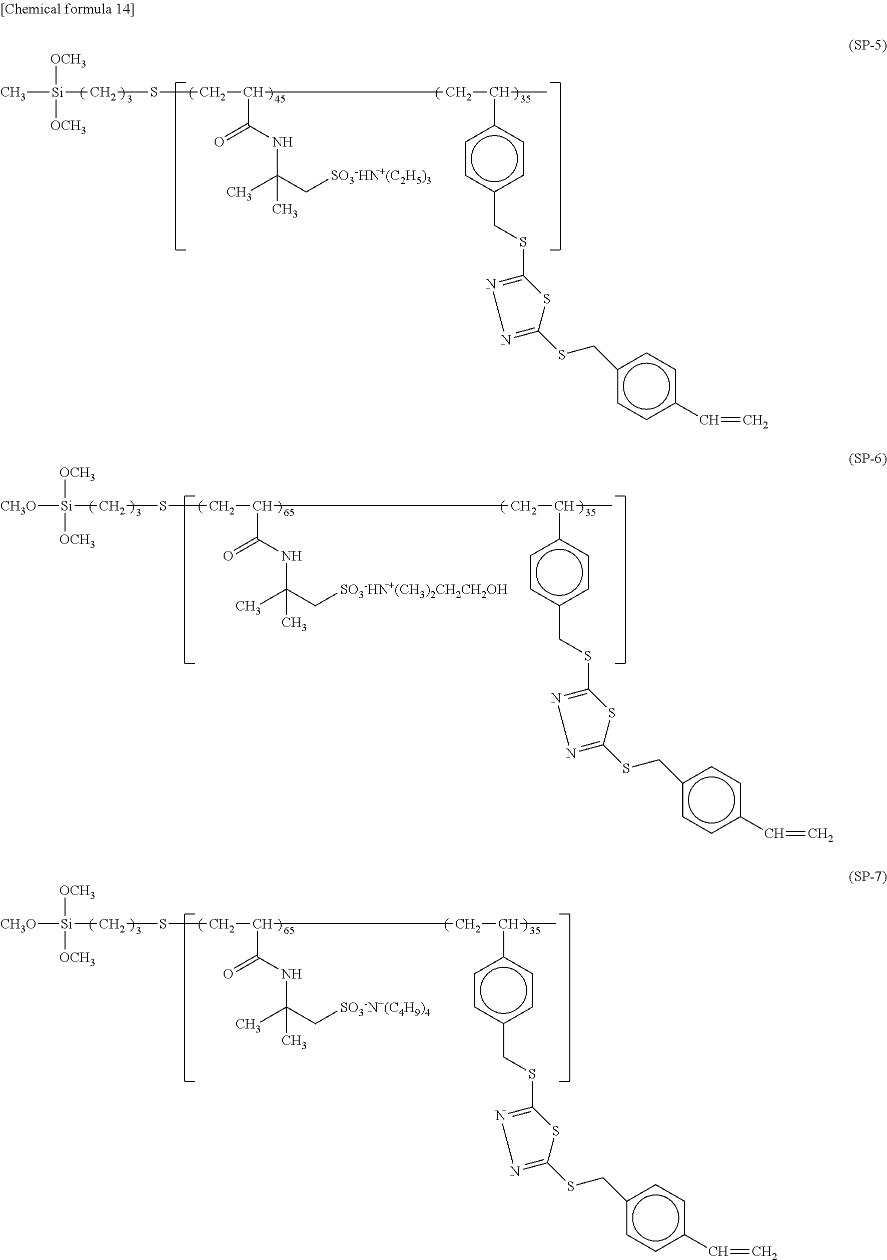

To be noted here is that a molar ratio of the mercapto compound of the general formula I and the whole monomer at the time of carrying out the above-mentioned radical polymerization is extremely important. The mercapto compound of the general formula I has at least two or more alkoxy groups in the molecule, and the alkoxy group is easily hydrolyzed in water in the presence of an acid or an alkali to become a hydroxyl group as well known in the art. It is also well known that the hydroxyl group is dehydrated or condensed to form a polysiloxane bond to form a polymer or an oligomer depending on the conditions. It is clear from the fact that, for example, when the compound of the general formula II is heated alone or in an aqueous acidic or alkaline solution, then a polysiloxane compound is precipitated from the solution. However, the inventors have found when the mercapto compound of the general formula I is introduced into the end of the main chain of the polymer of the present invention by the polymerization, the alkoxysilyl group represented by the above-mentioned formula II at the end of the polymer has extremely poor reactivity at the polymer ends with each other even when hydrolysis reaction is carried out and it is difficult to form a polysiloxane by condensation of the polymer ends. That is, when a molar number of the mercapto compound of the general formula I is 10 mol % or less based on the molar number of the whole monomer to be used, all the mercapto compound of the general formula I is substantially introduced into the end of the main chain of the polymer to provide terminal group structure represented by the general formula II. On the other hand, when the molar number of the mercapto compound of the general formula I is 10 mol % or more based on the molar number of the whole monomer to be used, there exists the mercapto compound of the general formula I which does not participate in the radical polymerization in the solution other than the group to be introduced into the end of the polymer main chain. In this case, when water exist in the polymerization system and the medium is an acidic or alkaline, the inventors have found that the mercapto compounds of the general formula I with each other, and the terminal group at the end of the main chain of the general formula II and the mercapto compound of the general formula I have been condensed to form a bond whereby a polysiloxane structure had been formed. In this case, as the polymer finally obtained, a polymer having a polymerizable double bond group and a carboxyl group or a sulfonate group at the side chain can be formed which is grafted to the polymer having a polysiloxane skeleton.

As explained above, in the two cases where a group represented by the above-mentioned general formula II is introduced into the end of the main chain of the polymer, and it is grafted to the polymer having a polysiloxane skeleton, it can be classified by the manner of addition of the mercapto compound represented by the general formula I. That is, when a monomer for providing a polymerizable double bond group to the side chain and a monomer having a carboxyl group or a sulfonate group are to be copolymerized, if said mercapto compound is added immediately before adding a polymerization initiator, polymerization proceed prior to formation of the polysiloxane by said mercapto compound, and said mercapto compound is effectively introduced into the end of the main chain of the polymer by the chain transfer reaction, whereby the group of the general formula II is to be selectively introduced into the end of the main chain of the polymer. Contrary to the above, by intentionally forming a polymer having a polysiloxane skeleton over a period of sufficient time so as to promote formation of a polysiloxanes before initiating the polymerization, graft polymerization to the same can be selectively caused.

In an application to the light-sensitive lithographic printing plate material which is an object of the present invention, the case where remarkable effects concerning improvement in plate preservation stability and to avoid background stain can be found out is, in the above-mentioned explanation, a case wherein a molar number of the mercapto compound of the general formula I is 10 mol % or less based on the molar number of the whole monomer to be used, preferably 0.5 mol % to 10 mol %, and further preferably 1 mol % to 10 mol %. In this case, a molecular weight of the formed polymer of the present invention is preferably, in terms of a weight average molecular weight, in the range of 5,000 to 200,000, more preferably in the range of 10,000 to 200,000, further preferably in the range of 20,000 to 150,000. If the molecular weight is larger than the above range, a ratio of the group of the general formula II as the terminal group occupied in the polymer is small so that the effects of the present invention cannot be obtained in some cases. Also, when the weight average molecular weight is less than 5,000, when it is utilized in the light-sensitive lithographic printing plate material mentioned below, printing endurance is inferior in some cases. A ratio of the molar number of the mercapto compound of the general formula I and the molar number of the whole monomer to give the molecular weight in the above range is preferably in the range of 0.005:1 to 0.1:1, more preferably in the range of 0.01:1 to 0.1:1, further preferably in the range of 0.02:1 to 0.1:1.

In an application for the light-sensitive lithographic printing plate material which is an object of the present invention, the case where particular effects are shown against the problem in line thinning during printing, the problem in decrease of dot area, and further lowering in ink transfer property during printing can be found out is, in the above-mentioned explanation, a case wherein a molar number of the mercapto compound of the general formula I is 10 mol % or more based on the molar number of the whole monomer to be used, preferably 10 mol % to 60 mol %, and further preferably 10 mol % to 40 mol %. In this case, as mentioned above, due to the mercapto compound of the general formula I existing in an amount more than acting as a chain-transfer agent, a polymer having a polysiloxane skeleton is formed in the polymerization system. The polysiloxane skeleton formed at this time may have different structures of the skeleton in the case where the mercapto compound of the general formula I has 2 alkoxy groups and in the case where it has 3 alkoxy groups. In the former case of having 2 groups, when R₁ is an alkyl group in the general formula I, a polymer having a linear polysiloxane skeleton as mentioned below is formed.

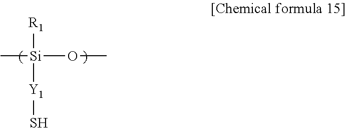

wherein R₁ and Y₁ have the same meanings as defined above.

When the mercapto compound of the general formula I has 3 alkoxy groups, a ladder type polysiloxane skeleton as shown in the following formula is formed.

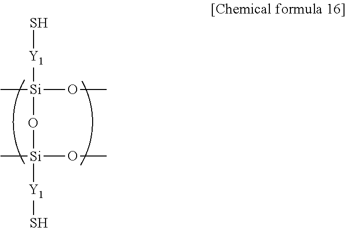

wherein Y₁ has the same meaning as defined above.

In the above-mentioned each case, when the monomer M is polymerized under such conditions, polymers in which the monomer M is grafted to the polysiloxane skeleton having the structure shown below are each formed. In the following formulae, m and m′ represent optional integer, and R₁ and Y₁ have the same meanings as defined above.

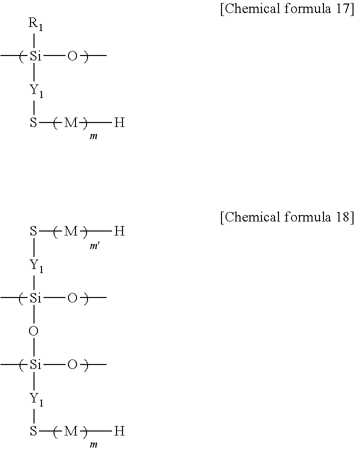

As mentioned above, those schematically shown by the monomer M in the above description is specifically a mixture to provide a copolymer comprising a monomer to provide a polymerizable double bond group and a monomer having a carboxyl group or a sulfonate group, at the side chain. Accordingly, the obtained polymer of the present invention in this case is a polymer in which a unit having the above-mentioned polyorganosiloxane structure and a unit having a polymerizable double bond group, and a carboxyl group or a sulfonate group at the side chain are bonded by a sulfur atom. A monomer to provide a polymerizable double bond group or a monomer to provide a carboxyl group or a sulfonate group, at the side chain may be mentioned the same monomer as the various monomers to be used for obtained a polymer having a group represented by the general formula II at the end of the main chain, and having a polymerizable double bond group, and a carboxyl group or a sulfonate group at the side chain shown above.

To form a unit having the polyorganosiloxane structure more clearly, it is preferred to employ a method in which the mercapto compound of the general formula I is subjected to hydrolysis in the presence of water, and following polycondensation prior to the polymerization, to form a polyorganosiloxane structural unit having a mercapto group at the side chain.

As the monomer to form the polyorganosiloxane structural unit, a compound which can be used in combination with the compound having the structure shown by the above-mentioned general formula I is shown by the following mentioned general formula V.

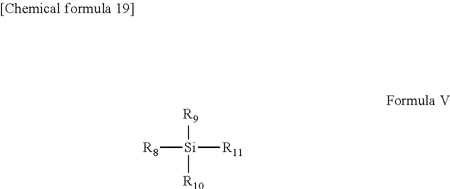

In the general formula V, the substituents R₈, R₉, R₁₀ and R₁₁ each represents an alkyl group having 1 to 10 carbon atoms such as a methyl group, ethyl group, etc., preferably 1 to 6 carbon atoms, further preferably 1 to 4 carbon atoms, an alkoxy group having 1 to 10 carbon atoms such as a methoxy group, ethoxy group, etc., preferably 1 to 6 carbon atoms, further preferably 1 to 4 carbon atoms, or an aryl group which may have a substituent(s) having 6 to 12 carbon atoms such as a phenyl group, etc., preferably 6 to 10 carbon atoms, provided that at least two of R₈, R₉, R₁₀ and R₁₁ are alkoxy groups. Preferred examples of the compound represented by the general formula V may be mentioned compounds such as tetramethylorthosilicate, tetraethylorthosilicate, tetrapropylorthosilicate, tetrabutylorthosilicate, methyltrimethoxysilane, methyltriethoxysilane, ethyltrimethoxysilane, ethyltriethoxysilane, trimethoxypropylsilane, isobutyltrimethoxysilane, octyltrimethoxysilane, octadecyltrimethoxysilane, phenyltrimethoxysilane, phenyltriethoxysilane, dimethyldimethoxysilane, dimethyldiethoxysilane, etc., and a plural kinds of compounds may be selected from these compounds.

By using the mercapto compound represented by the general formula I alone or in combination with the silane compound represented by the general formula V, and they are subjected to hydrolysis in the presence of water, and following polycondensation to form a polyorganosiloxane structural unit having a mercapto group at the side chain.

Here, in the latter case of the above, i.e., when the mercapto compound represented by the general formula I and the silane compound represented by the general formula V are used in combination to provisionally synthesize a polyorganosiloxane having a mercapto group at the side chain, and then, the above-mentioned graft polymerization is to be carried out in the presence of the above, a ratio of the whole molar number in which the molar numbers of the mercapto compound of the general formula I and the silane compound of the general formula V are combined based on the molar number of the whole monomer to be used in the graft polymerization is preferably 10 mol % or more, and similarly in the case where a polyorganosiloxane is synthesized by the mercapto compound of the general formula I alone and it is used for the graft polymerization, preferably 10 mol % to 60 mol %, further preferably 10 mol % to 40 mol %.

At the time of hydrolysis and polycondensation of the above-mentioned mercapto compound of the general formula I or the silane compound of the general formula V to be used therewith, by carrying out the reaction in the presence of water which exceeds whole molar number of the both silane compounds in acidic or alkaline conditions, the polyorganosiloxane structural unit can be formed with good yield. As the acid catalyst to be used under the acidic conditions, there may be mentioned an inorganic acid such as hydrochloric acid, nitric acid, sulfuric acid, etc., or an organic acid such as p-toluenesulfonic acid, p-toluenesulfonic acid monohydrate, sulfonic acid, methanesulfonic acid, ethanesulfonic acid, acetic acid, formic acid, etc.

Also, as the base catalyst to be used under the basic conditions, there may be used a metal hydroxide such as sodium hydroxide, potassium hydroxide, magnesium hydroxide, calcium hydroxide, etc., a carbonate such as sodium carbonate, sodium hydrogen carbonate, potassium carbonate, potassium hydrogen carbonate, etc., or a metal alkoxide such as sodium methoxide, sodium ethoxide, potassium methoxide, potassium t-butoxide, magnesium methoxide, magnesium ethoxide, etc., and further, there may be preferably used a primary amine such as methylamine, ethylamine, butylamine, monoethanolamine, etc., a secondary amine such as diethylamine, dibutylamine, etc., a tertiary amine such as triethylamine, diisopropylethylamine, dimethylaminoethanol, triethanolamine, etc., and further a nitrogen-containing heterocyclic ring compound such as pyridine, 1,8-diazabicyclo[5.4.0]undec-7-ene (DBU), etc.

An amount of the acid catalyst or base catalyst to be used is generally in the range of 0.001 parts by weight to 25 parts by weight, preferably 0.01 parts by weight to 20 parts by weight based on the total silane compound to be used as 100 parts by weight. The reaction temperature is generally a temperature range of from 0° C. to a boiling point of the solvent to be used, preferably in the range of 15° C. to 130° C. If the reaction temperature is too low, there is a case where progress of the condensation reaction becomes insufficient. On the other hand, if the reaction temperature is too high, it becomes difficult to prevent from gellation. The reaction is generally completed within several minutes to several 10 hours.

There is a preferred range in the molecular weight of the polyorganosiloxane structural unit, and it is preferably in the range of from 500 to 20,000, more preferably in the range of 1,000 to 10,000, further preferably in the range of 1,000 to 8,000 in a weight average molecular weight in terms of polystyrene. If it is less than the above molecular weight, there is a case where the effects of the present invention are not obtained in some cases. Also, if the molecular weight exceeds 20,000, there is a case where a solvent-insoluble gel is formed in some cases whereby a uniform polymer of the present invention cannot be obtained in some cases.

When the polymer of the present invention is to be obtained by synthesizing a precursor polymer which is grafted to a polyorganosiloxane structural unit, and then, a polymerizable double bond group is introduced into said precursor polymer, the method for introducing the polymerizable double bond group is the same as the case of the polymer of the present invention having a group of the general formula II at the end of the main chain mentioned above. With regard to the specific synthetic method, it is explained in more detail by the following mentioned Synthetic examples.

The light-sensitive lithographic printing plate material of the present invention is characterized in that the photo-curable light-sensitive layer on the support is synthesized by using the compound represented by the above-mentioned formula I, and contains the polymer having a polymerizable double bond group, and a carboxyl group or a sulfonate group at the side chain, and as the other components, there may be mentioned the following components.

In the photo-curable light-sensitive layer of the light-sensitive lithographic printing plate material according to the present invention, a photopolymerization initiator generating a radical by photo-irradiation is preferably contained. In the present invention, optional compounds can be used so long as it basically forms a radical other than the following exemplified various compounds. As the photopolymerization initiator, there may be mentioned, for example, (a) aromatic ketones, (b) organic peroxides, (c) hexaarylbiimidazole compounds, (d) ketoxime ester compounds, (e) azinium compounds, (f) titanocene compounds, (g) trihaloalkyl-substituted compounds and (h) organic boron salt compounds, etc.

Preferred examples of the (a) aromatic ketones as the photopolymerization initiator may be mentioned, a compound having a benzophenone skeleton or thioxanthone skeleton, α-thiobenzophenone compounds disclosed in JP S47-6416B, benzoin ether compounds disclosed in JP 547-3981B, α-substituted benzoin compounds disclosed in JP 547-22326B, benzoin derivatives disclosed in JP 547-23664B, aroylphosphonic acid esters disclosed in JP 557-30704B, dialkoxybenzophenones disclosed in JP 560-26483B, benzoin ethers disclosed in JP S60-26403B and JP S62-81345A, p-di(dimethylaminobenzoyl)benzene disclosed in JP H2-211452A, a thio-substituted aromatic ketone disclosed in JP S61-194062A, acylphosphine sulfide disclosed in JP H2-9597B, acylphosphine disclosed in JP H2-9596B, thioxanthones disclosed in JP S63-61950B, coumarines disclosed in JP S59-42864B.

As the (b) organic peroxide which is other examples of the photopolymerization initiator according to the present invention, almost all the organic compounds having one or more oxygen-oxygen bondings in the molecule are included, and there may be preferably mentioned, for example, peroxide esters such as 3,3′,4,4′-tetra(t-butylperoxycarbonyl)benzophenone, 3,3′,4,4′-tetra(t-amylperoxycarbonyl)benzophenone, 3,3′,4,4′-tetra(t-hexylperoxycarbonyl)benzophenone, 3,3′,4,4′-tetra(t-octylperoxycarbonyl)benzophenone, 3,3′,4,4′-tetra(cumylperoxycarbonyl)benzophenone, 3,3′,4,4′-tetra(p-isopropylcumylperoxycarbonyl)benzophenone, di-t-butyl-diperoxyisophthalate, etc.

As the (c) hexaarylbiimidazole which is other examples of the photopolymerization initiator preferably used in the present invention, there may be mentioned lophine dimers disclosed in JP S45-37377B and JP S44-86516B, for example, 2,2′-bis(o-chlorophenyl)-4,4′,5,5′-tetraphenylbiimidazole, 2,2′-bis(o-bromophenyl)-4,4′,5,5′-tetraphenylbiimidazole, 2,2′-bis(o,p-dichlorophenyl)-4,4′,5,5′-tetraphenylbiimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenylbiimidazole, 2,2′-bis(o-nitrophenyl)-4,4′,5,5′-tetraphenylbiimidazole, 2,2′-bis(o-methylphenyl)-4,4′,5,5′-tetraphenylbiimidazole, 2,2′-bis(o-trifluoromethylphenyl)-4,4′,5,5′-tetraphenylbiimidazole, etc.

As the (d) ketoxime ester which is other examples of the photopolymerization initiator according to the present invention, there may be mentioned 3-benzoyloxy-iminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-p-toluenesulfonyloxyiminobutan-2-one, 2-ethoxy-carbonyloxyimino-1-phenylpropan-1-one, etc.

Examples of the (e) azinium salt compound which is other examples of the photopolymerization initiator may be mentioned compound groups having a N—O bond as disclosed in JP S63-138345A, JP S63-142345A, JP S63-142346A, JP S63-143537A and JP S46-42363B.

Examples of the (f) titanocene compound which is other examples of the photopolymerization initiator may be mentioned, for example, various titanocene compounds as disclosed in JP S59-152396A, JP S61-151197A, JP S63-41483A, JP S63-41484A, JP H2-249A, JP H2-291A, JP H3-27393A, JP H3-12403A, JP H6-41170A, etc., and they can be preferably used. Specific titanocene compounds may be mentioned, for example, di-cyclopentadienyl-Ti-di-chloride, di-cyclopentadienyl-Ti-bis-phenyl, di-cyclopentadienyl-Ti-bis-2,3,4,5,6-pentafluorophen-1-yl, di-cyclopentadienyl-Ti-bis-2,3,5,6-tetrafluorophen-1-yl, di-cyclopentadienyl-Ti-bis-2,4,6-trifluorophen-1-yl, di-cyclopentadienyl-Ti-2,6-di-fluorophen-1-yl, di-cyclopentadienyl-Ti-bis-2,4-di-fluorophen-1-yl, di-methylcyclopentadienyl-Ti-bis-2,3,4,5,6-pentafluorophen-1-yl, di-methylcyclopentadienyl-Ti-bis-2,6-difluorophen-1-yl, di-cyclopentadienyl-Ti-bis-2,6-difluoro-3-(pyr-1-yl)-phen-1-yl, etc.

As the other examples of the photopolymerization initiator, there may be mentioned (g) trihaloalkyl-substituted compound. The trihaloalkyl-substituted compound herein mentioned specifically means a compound having at least one trihaloalkyl group such as a trichloromethyl group, tribromomethyl group, etc., in the molecule. Preferred examples may be mentioned s-triazine derivatives and oxadiazole derivatives as a compound in which said trihaloalkyl group is bonded to a nitrogen-containing heterocyclic ring group, or trihaloalkylsulfonyl compounds in which said trihaloalkyl group is bonded to an aromatic ring or nitrogen-containing heterocyclic ring through a sulfonyl group. Examples of the preferred trihaloalkyl-substituted compounds are mentioned below.

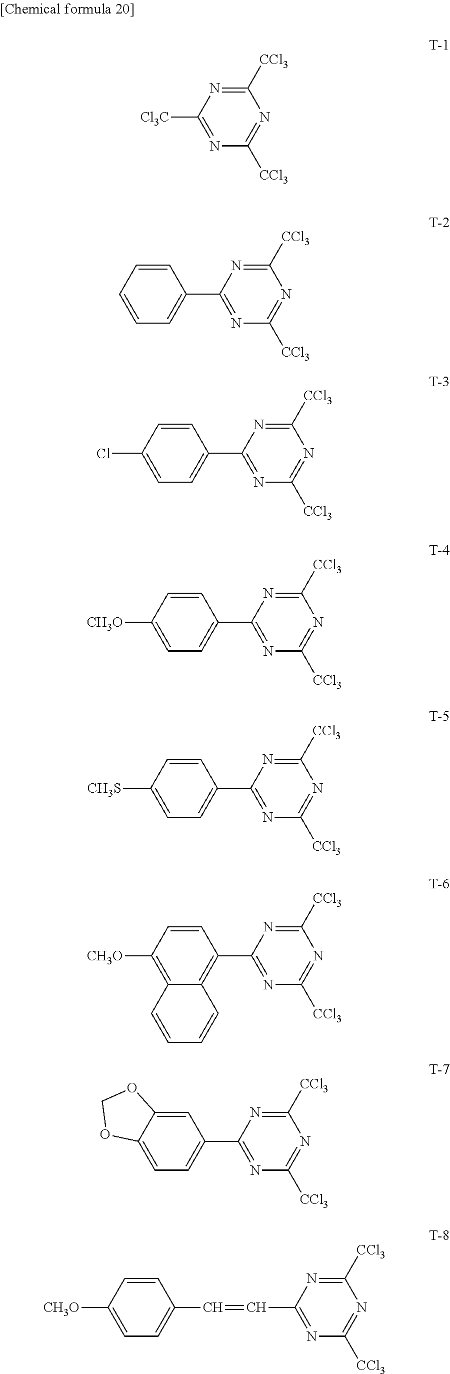

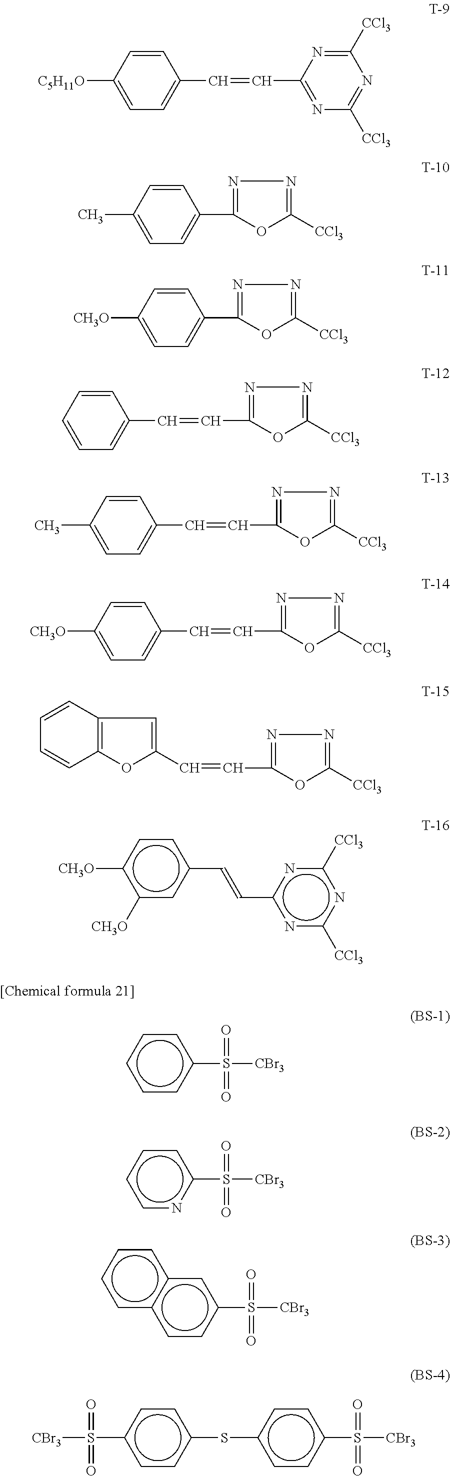

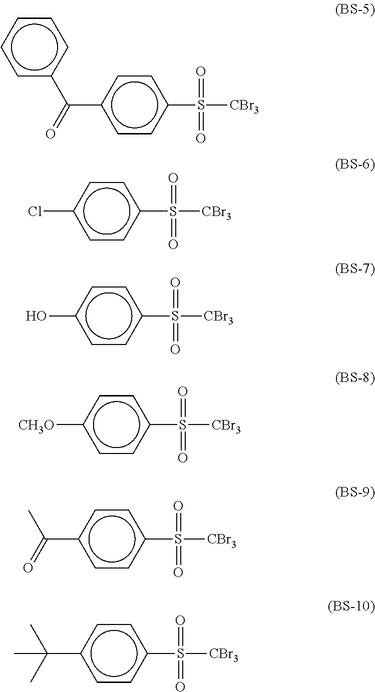

As the preferred photopolymerization initiator according to the present invention, (h) an organic boron salt compound can be mentioned, and a compound having an organic boron anion represented by the following mentioned general formula VI is particularly preferably used.

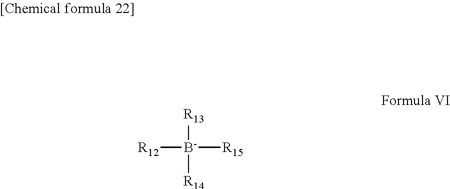

In the above formula, R₁₂, R₁₃, R₁₄ and R₁₅ each may be the same or different from each other, and each represent an alkyl group, an aryl group, an aralkyl group, an alkenyl group, an alkynyl group, a cycloalkyl group, a heterocyclic ring group. Of these, particularly preferred is the case where one of the R₁₂, R₁₃, R₁₄ and R₁₅ is an alkyl group, and the other substituents are aryl groups.

In the above-mentioned organic boron anion, a cation which forms a salt therewith is simultaneously present. As the cation in this case, there may be mentioned an alkali metal ion, onium ion and cationic sensitizing dye. As the onium salt, there may be mentioned an ammonium, sulfonium, iodonium and phosphonium compound. When a salt of the alkali metal ion or onium compound and the organic boron anion is to be used, a sensitizing dye is separately added to provide light-sensitivity in the wavelength of the light absorbed by the dye. Also, when an organic boron anion is contained as a counter anion of the cationic sensitizing dye, light-sensitivity is provided depending on an absorption wavelength of said sensitizing dye. However, in the latter case, an organic boron anion is preferably further contained in combination as a counter anion of the alkali metal or onium salt.

As the organic boron salt to be used in the present invention, there may be mentioned a salt containing the organic boron anion represented by the aforementioned general formula VI, and as a cation which forms a salt, there may be preferably used an alkali metal ion and an onium compound. Particularly preferred example may be mentioned, as an onium salt with the organic boron anion, ammonium salts such as tetraalkyl ammonium salt, etc., sulfonium salts such as triarylsulfonium salt, etc., and phosphonium salts such as triarylalkylphosphonium salt, etc. Particularly preferred examples of the organic boron salt are mentioned below.

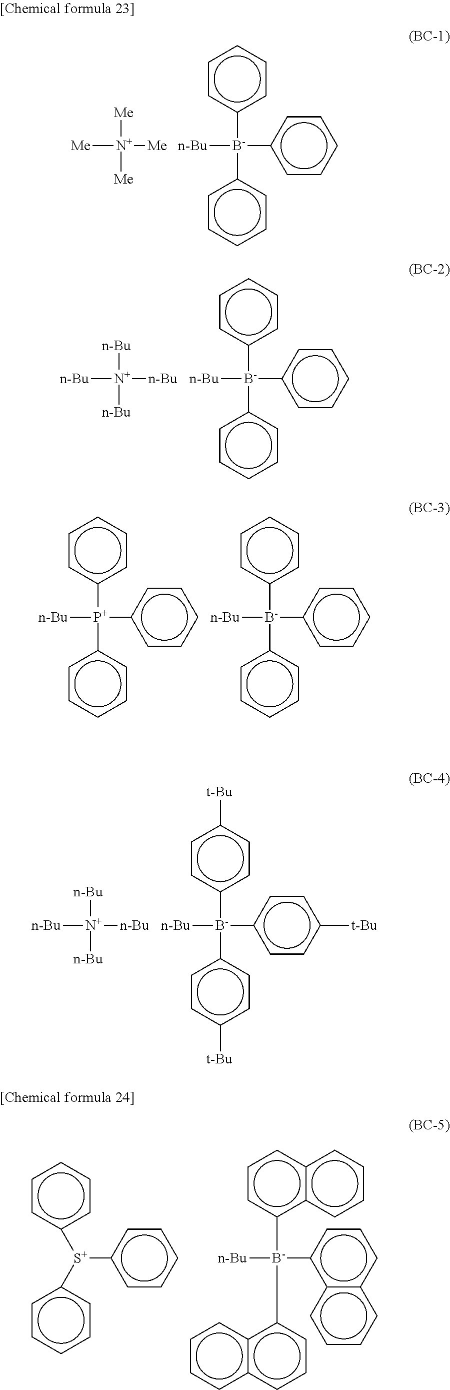

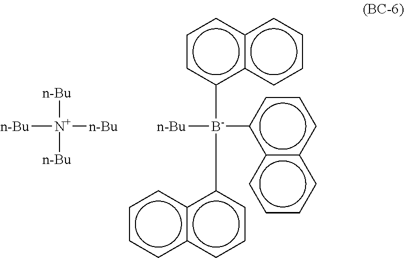

As a photopolymerization initiator which can be most preferably used in the present invention, there may be mentioned the above-mentioned trihaloalkyl-substituted compound and organic boron salt compound, or the case where these are used in combination.

There exist a preferred range in a ratio of amounts of the above-mentioned photopolymerization initiator and the polymer of the present invention, and the photopolymerization initiator is preferably used in the range of 0.1 to 30 parts by weight based on 100 parts by weight of said polymer, and further, particularly preferably in the range of 0.2 to 20 parts by weight.

As the most preferred photopolymerization initiator to provide a light-sensitive lithographic printing plate material which is excellent in plate preservation stability and background stain property, or excellent in adhesiveness or abrasion resistance which are objects of the present invention, there may be mentioned an organic boron salt compound, and also a system in which the above-mentioned trihaloalkyl-substituted compound and the organic boron salt are contained in combination. By using the both components in combination, photocurability can be synergistically promoted, and extremely good adhesiveness and abrasion resistance can be realized in combination with the polymer of the present invention.

In the photo-curable light-sensitive layer of the light-sensitive lithographic printing plate material according to the present invention, it is preferred to contain a compound having a peak of sensitivity with a light wavelength region of 400 to 430 nm or 750 to 1100 nm, having an absorption in this wavelength region, and sensitizing the above-mentioned photopolymerization initiator in combination. The compounds which increase the sensitivity at the wavelength region of 400 to 430 nm may be mentioned cyanine series dyes, coumarine series compounds as disclosed in JP H7-271284A, JP H8-29973A, etc., carbazole series compounds as disclosed in JP H9-230913A, JP 2001-42524A, etc., carbomelocyanine series dyes as disclosed in JP H8-262715A, JP H8-272096A, JP H9-328505A, etc., aminobenzylidene ketone series dyes as disclosed in JP 114-194857A, JP 116-295061A, JP H7-84863A, JP H8-220755A, JP H9-80750A, JP H9-236913A, etc., pyromethine series dyes as disclosed in JP H4-184344A, JP H6-301208A, JP H7-225474A, JP H7-5685A, JP H7-281434A, JP H8-6245A, etc., styryl series dyes, or (thio)pyrylium series compounds as disclosed in JP H9-80751A, etc. Of these, cyanine series dyes, coumarine series compounds or (thio)pyrylium series compounds are preferred. Examples of the cyanine series dyes preferably used are mentioned below.

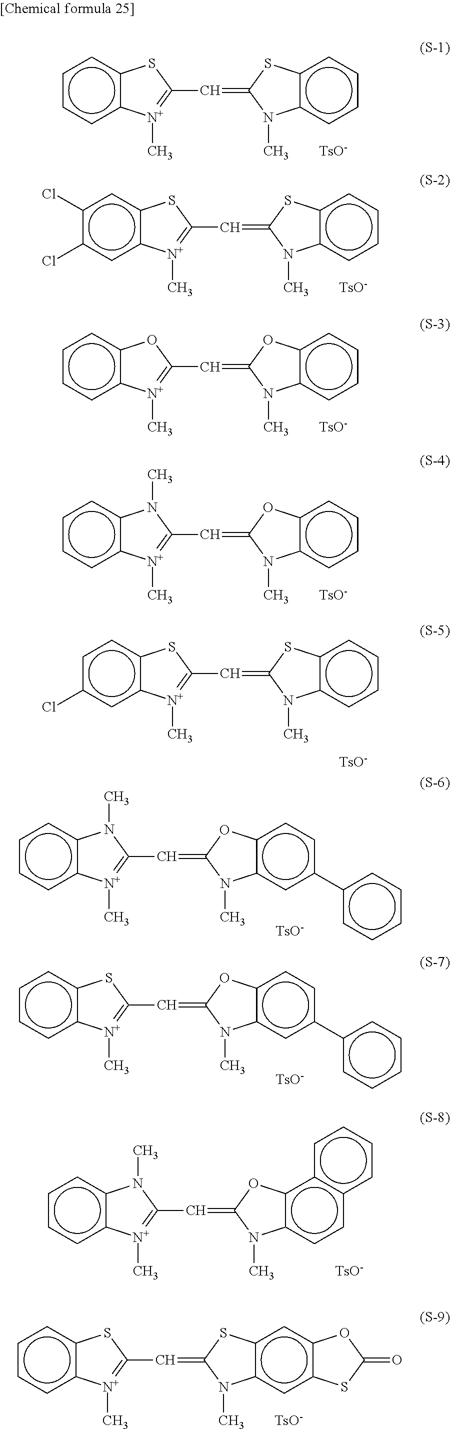

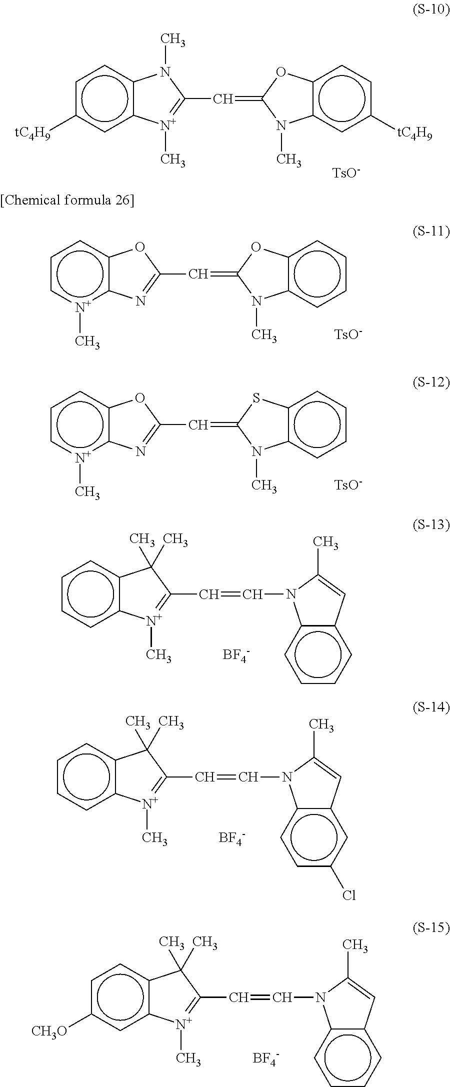

Examples of coumarine series compound which can be used to increase the sensitivity in the wavelength region of 400 to 430 nm are mentioned below.

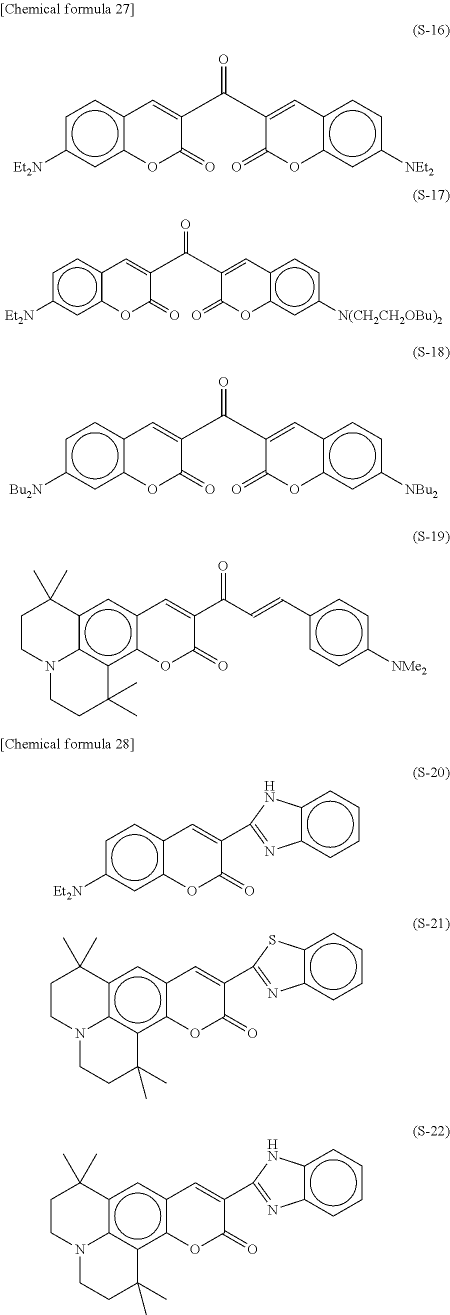

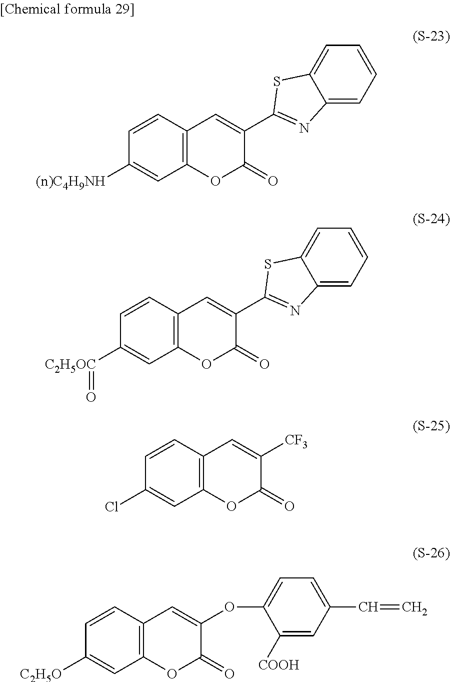

Preferred examples of the (thio)pyrylium series compound which can be used to increase the sensitivity in the wavelength region of 400 to 430 nm are mentioned below.

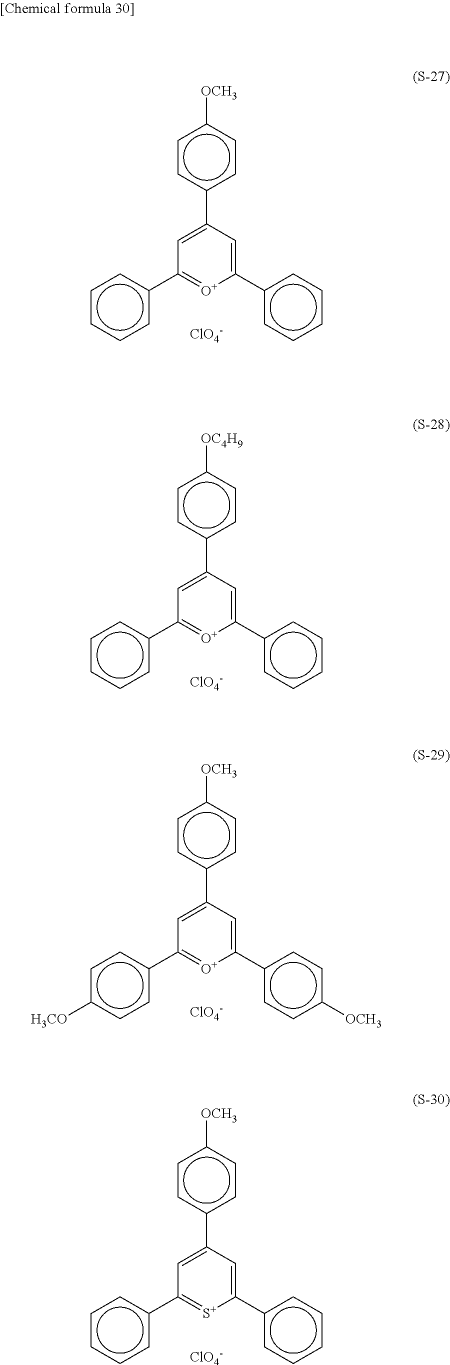

As a sensitizing dye in the wavelength region of 750 to 1100 nm, there may be mentioned cyanine series dyes, porphyrin, spiro compounds, ferrocene, fluorene, fulgide, imidazole, perylene, phenazine, phenothiazine, polyene, azo series compounds, diphenylmethane, triphenylmethane, polymethineacridine, coumarin, ketocoumarine, quinacridone, indigo, styryl, squarylium series compounds, and (thio)pyrylium series compounds, and further, the compounds disclosed in EP Patent No. 568,993, U.S. Pat. No. 4,508,811 and U.S. Pat. No. 5,227,227 can be used.

Preferred examples of sensitizing dyes which correspond to near infrared light in the wavelength region of 750 to 1100 nm are mentioned below.

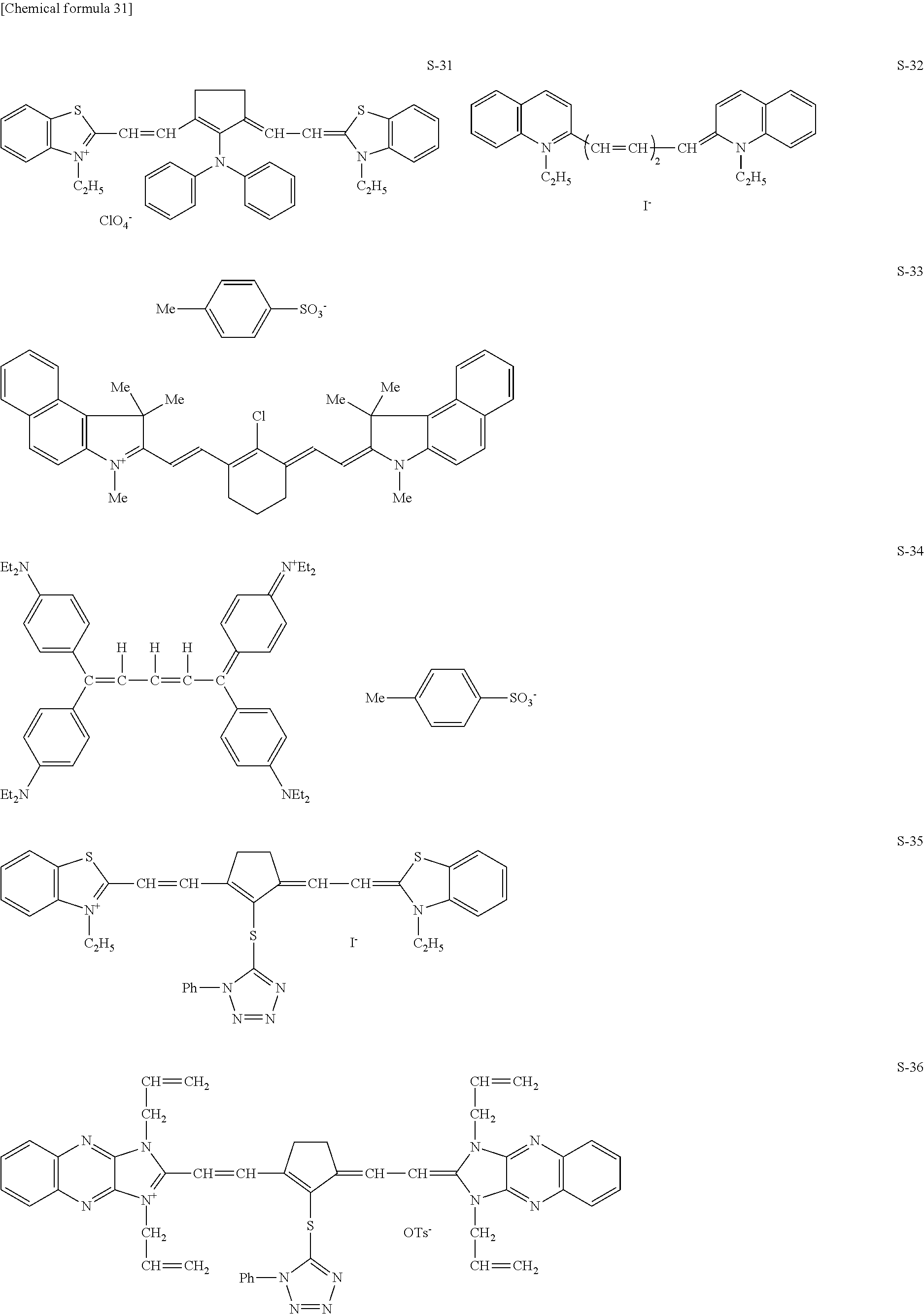

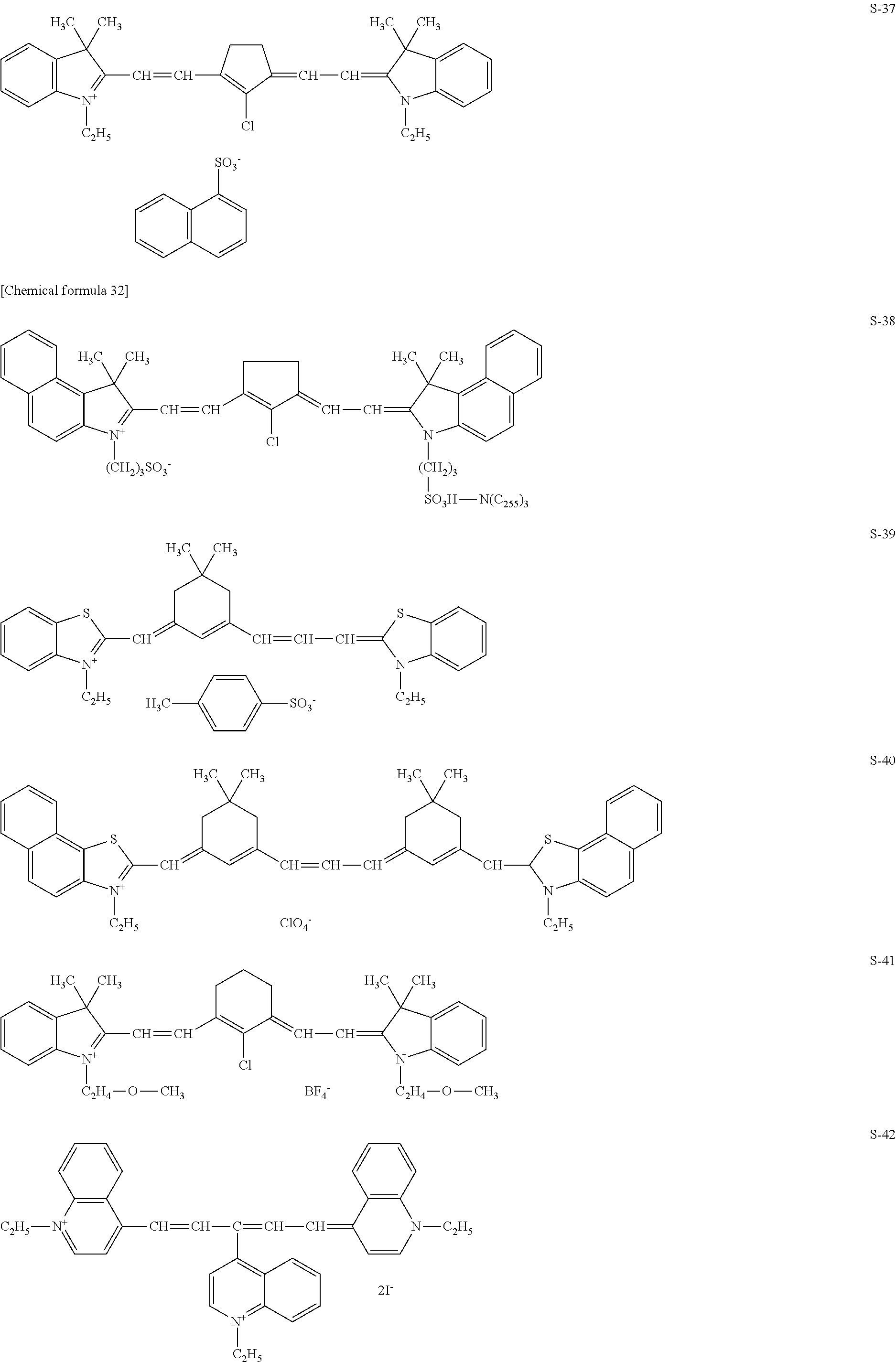

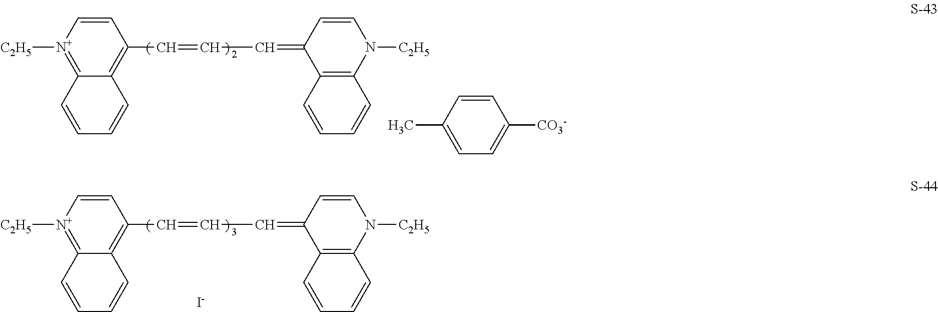

In the photo-curable light-sensitive layer possessed by the light-sensitive lithographic printing plate material of the present invention, a polyfunctional monomer may be contained. Examples of such a polyfunctional monomer may be mentioned a polyfunctional acrylic monomer such as 1,4-butanediol di(meth)acrylate, 1,6-hexane-diol di(meth)acrylate, neopentylglycol di(meth)acrylate, tetraethylene glycol di(meth)-acrylate, trisacryloyloxyethylisocyanurate, tripropylene glycol di(meth)acrylate, trimethylolpropane tri(meth)acrylate, pentaerythritol tri(meth)acrylate, pentaerythritol tetra(meth)acrylate, etc., or as various polymers into which a (meth)acryloyl group has been introduced, there may be mentioned polyester(meth)acrylate, urethane(meth)-acrylate, epoxy(meth)acrylate, etc. When such a polyfunctional monomer is used with the polymer of the present invention, it is preferably used in a ratio of 100 parts by weight or less based on 100 parts by weight of the polymer of the present invention.

As other element(s) for constituting the photo-curable light-sensitive layer, it is preferably carried out to add various dyes and pigments for the purpose of heightening visibility of an image, or to add inorganic fine particles or organic fine particles for the purpose of preventing blocking of the light-sensitive composition and others.

To the photo-curable light-sensitive layer, a polymerization inhibitor is preferably added to prevent from curing reaction by thermal polymerization in a dark place during the long term preservation. As the polymerization inhibitor to be used for the above purpose, there may be preferably used various kinds of compounds having phenolic hydroxyl group(s) such as hydroquinones, catechols, naphthols, cresols, etc., quinone compounds, 2,2,6,6-tetramethylpiperidine-N-oxyls, N-nitrosophenylhydroxylamine salts, etc. An added amount of the polymerization inhibitor to be used in this case is preferably in the range of 0.01 parts by weight to 10 parts by weight based on the total solid content of the photo-curable light-sensitive layer as 100 parts by weight.

As the support of the light-sensitive lithographic printing plate material according to the present invention, there may be mentioned various plastic film supports and aluminum plates. As the plastic film supports, there may be representatively mentioned polyethylene terephthalate, polyethylene naphthalate, polyethylene, polypropylene, polystyrene, polyvinyl acetal, polycarbonate, cellulose diacetate, cellulose triacetate, cellulose propionate, cellulose butyrate, cellulose nitrate, etc., and polyethylene terephthalate or polyethylene naphthalate is particularly preferably used. The surfaces of these films are preferably subjected to hydrophilic treatment on the film surface thereof before providing a layer using the light-sensitive lithographic printing plate material of the present invention.

Such a hydrophilic processing may be mentioned a corona discharge treatment, flame treatment, plasma treatment, UV irradiation treatment, etc. As a further hydrophilic treatment, it may be preferably carried out by providing a layer containing various water-soluble polymers on the film. For example, it is preferably carried out to form a hydrophilic layer comprising a water-soluble polymer, colloidal silica and a cross-linking agent as described in the above-mentioned JP 2008-250195A (Patent Literature 1) on the above-mentioned film. Moreover, a subbing layer may be provisionally provided on the film to heighten adhesiveness with the hydrophilic layer to be provided therein. As the subbing layer, a layer mainly comprising a hydrophilic resin is effective. As the hydrophilic resin, preferably used are hydrophilic resins such as gelatin, gelatin derivative (for example, phthalated gelatin), hydroxyethyl cellulose, carboxymethyl cellulose, methyl cellulose, hydroxypropylmethyl cellulose, ethylhydroxyethyl cellulose, polyvinylpyrrolidone, polyethylene oxide, xanthane, cationic hydroxyethyl cellulose, polyvinyl alcohol, polyacrylamide, etc. Particularly preferred are gelatin and polyvinyl alcohol. By forming the film support and the hydrophilic layer via such a subbing layer, printing endurance under the long-run conditions with a large number of printing sheets is improved so that it is preferably utilized.

When an aluminum plate is used as the support, an aluminum plate having an anodized film which had been subjected to roughening treatment is preferably used. Moreover, an aluminum plate a surface of which is subjected to silicate treatment is also preferably used. Or else, an aluminum plate on the surface of which is formed the above-mentioned hydrophilic layer may be used.

For forming a light-sensitive lithographic printing plate material by forming a photo-curable light-sensitive layer on the above-mentioned support, it is preferred that a layer containing the polymer of the present invention, a photopolymerization initiator, a sensitizer and other materials mentioned above is formed on the support surface as a photo-curable light-sensitive layer or on the support surface via the above-mentioned hydrophilic layer. With regard to a coating amount of a dry solid content of the photocurable light-sensitive layer itself in this case, it is preferably formed with a coating amount of the dry solid content in the range of 0.3 g to 10 g per 1 m² with a dry weight, and further when it is in the range of 0.5 g to 3 g, it develop good resolution, and ensures printing endurance of fine line image or fine dot image, and simultaneously abrasion resistance can be markedly improved so that it is particularly preferred. The photo-curable light-sensitive layer was formed by preparing a solution in which the above-mentioned various elements are mixed, and coating on the support surface or on the hydrophilic layer by using conventionally known various coating systems and dried.

In the light-sensitive lithographic printing plate material of the present invention, it is also preferably carried out to further form a protective layer on the photo-curable light-sensitive layer comprising the photopolymerizable composition. The protective layer has preferred effects that it prevents from migration of a low molecular weight compound such as oxygen or basic substance, etc. existing in the air, which inhibits an image forming reaction caused by exposure in the light-sensitive layer into the light-sensitive layer, and further improves exposure sensitivity in the air. Moreover, it is also expected to have an effect that the surface of the light-sensitive layer is prevented from flaw. Accordingly, the characteristics desired for such a protective layer are low transmittance of a low molecular weight compound such as oxygen, etc., excellent in dynamic strength, further, substantially not inhibit transmission of light to be used for exposure, excellent in adhesiveness with the light-sensitive layer, and, easily removable during the developing step after exposure. In the water developable light-sensitive lithographic printing plate material of the present invention, it is possible to simultaneously remove such a protective layer and an unexposed portion of the photo-curable light-sensitive layer during the course of water development, so that it is a characteristics that no removal step of the protective layer is particularly provided. Moreover, since said polymer contained in the photo-curable light-sensitive layer as mentioned above is water-soluble so that there are some cases causing problems that it absorbs moisture in the air to cause blocking, or causing change in sensitivity during preservation. However, by providing a protective layer at the upper portion of the photo-curable light-sensitive layer, it is possible to cancel these problems such as blocking and change in sensitivity. In addition, when recording is carried out particularly by using a blue-purple color semiconductor laser having a wavelength region of 400 to 430 nm, laser output is generally lower as compared with that of a near infrared semiconductor laser, so that a light-sensitive layer having particularly high sensitivity is required. In such a case, by providing a protective layer, sensitivity is further increased so that it can be particularly preferably applied.

Such a device concerning the protective layer has heretofore been carried out, and described in detail in U.S. Pat. No. 3,458,311, JP S55-49729A, etc. As a material which can be used for the protective layer, there may be preferably used, for example, a water-soluble polymer compound which is relatively excellent in crystallinity. More specifically, a water-soluble polymer such as a polyvinyl alcohol, polyvinylpyrrolidone, acidic celluloses, gelatin, gum Arabic, polyacrylic acid, etc., has been known, and of these, when polyvinyl alcohol is used as a main component, most excellent results can be obtained on the basic characteristics such as an oxygen shielding property, removability in development. The polyvinyl alcohol to be used in the protective layer may be substituted by an ester, ether, and acetal in a part thereof so long as it contains an unsubstituted vinyl alcohol unit for having necessary oxygen-shielding property and water-solubility. Also, a part thereof may have other copolymerizable component similarly. With regard to a coating amount with a dry solid content when such a protective layer is to be applied, there exist a preferred range, and the coating amount with the dry solid content is preferably formed on the light-sensitive layer in terms of a dry weight in the range of 0.1 g to 10 g per 1 m² in a dry weight, more preferably in the range of 0.2 g to 2 g. The protective layer is coated on the photo-curable light-sensitive layer by using the conventionally known various coating systems and dried.

For using a material having a photo-curable light-sensitive layer formed on a support as mentioned above as a printing plate, it is subjected to contact exposure or laser scanning exposure, whereby the exposed portions are cross-linked so that their solubilities are lowered, and the unexposed portion is dissolved out by using a neutral developing solution having a pH of less than 9 or an alkali developing solution having a pH in the range of 9 to 12 to carry out pattern formation.

In the present invention, a neutral developing solution having a pH of less than 9 means a pH in the range of 4 to less than 9, preferably a pH in the range of 6 to less than 9, and most preferably it contains substantially no chemical agent. Provided that depending on developability of the light-sensitive lithographic printing plate material, various inorganic or organic ionic compounds may be contained in pure water with a concentration of 1% by weight or less, and it may be water containing a sodium, potassium, calcium, magnesium ion, etc. Or else, various surfactants, etc., may be contained in water with a concentration of 1% by weight or less. Also, various alcohols such as methanol, ethanol, propanol, isopropanol, ethylene glycol, propylene glycol, methoxyethanol, polyethylene glycol, etc., may be contained in water as a solvent with a concentration of 1% by weight or less. Or else, at the time of development, commercially available various gum liquids are added in a concentration of 1% by weight or less and development may be preferably carried out for the purpose of protecting the plate surface from fingerprint stain, etc. Even when these chemicals such as various inorganic or organic ionic compounds, various surfactants, or a solvent(s), or a gum liquid(s), etc., are contained in pure water singly or in admixture, these chemicals are preferably used in terms of % by weight concentration of 3% by weight or less in the neutral developing solution according to the present invention.

The light-sensitive lithographic printing plate material of the present invention can show good characteristics as a printing plate even when an alkali developing solution having a pH in the range of 9 to 12 other than the above-mentioned neutral developing solution. Such a developing solution may contain a surfactant and an alkaline agent. In the developing solution, an organic solvent, buffer, chelating agent, etc., may be further contained. Suitable alkaline agent may be mentioned an inorganic alkaline agent such as sodium hydroxide, potassium hydroxide, lithium hydroxide, sodium triphosphate, sodium diphosphate, sodium carbonate, potassium carbonate, sodium bicarbonate, etc., or an organic amine compound such as trimethylamine, diethylamine, isopropylamine, n-butylamine, monoethanolamine, diethanolamine, triethanolamines, etc., and these compounds may be used singly or in combination. As the surfactant, there may be used, for example, nonionic surfactants such as polyoxyethylene alkyl ethers, polyoxyethylene alkylaryl ethers, polyoxyethylene alkyl esters, sorbitan alkyl esters, monoglyceride alkyl esters, etc.; anionic surfactants such as alkylbenzenesulfonates, alkylnaphthalenesulfonates, alkylsulfates, alkylsulfonates, sulfosuccinate esters, etc.; and amphoteric surfactants such as alkylbetaines, amino acids, etc. Also, as organic solvents, it is possible to contain, for example, isopropyl alcohol, benzylalcohol, ethyl cellosolve, butyl cellosolve, phenyl cellosolve, propylene glycol, diacetone alcohol, etc., if necessary.

Moreover, a developing solution containing tetraalkyl ammonium hydroxide with a pH 10 to 12 as described in JP 2006-39177A or JP 2006-64952A, etc., can be preferably used. As the alkyl group of the tetraalkyl ammonium hydroxide in this case, an alkyl group having 1 to 6 carbon atoms is preferred, and an alkyl group having 1 to 4 carbon atoms is particularly preferred. These alkyl groups may be further substituted by a hydroxyl group, an alkoxy group such as a methoxy group, etc.

The developing method is not particularly limited, and there may be mentioned a method in which the material is dipped in a developing solution, a method in which a non-image portion which is being dissolved by a developing solution is removed physically by a brush, etc., a method in which a developing solution is sprayed to the material to remove a non-image portion, and the like. A developing time may be selected depending on the above-mentioned developing method so that an unexposed portion can be sufficiently removed, and optionally selected from the range of 5 seconds to 10 minutes. After development, particularly in the printing plate, a hydrophilic treatment, etc., using gum Arabic, etc., may be optionally carried out. Also, if necessary, an oxygen-shielding layer may be previously washed before development.

After subjecting to developing treatment as mentioned above, a gum coating treatment for the purpose of protecting the plate surface may be carried out to prevent the surface of the printing plate from flaw or stain by using a gum liquid such as gum Arabic, etc.

### EXAMPLES

In the following, the present invention is explained in more detail by referring to Examples, but the present invention is not limited by these Examples. All part(s) and percentage(s) in the Examples are based on a weight otherwise specifically mentioned.

### Synthetic Example 1

### Synthetic Example of Polymer AP-4

According to the Synthetic example described in JP 2001-290271A, a compound (hereinafter referred to as M-1) represented by the chemical formula M-1 was obtained from p-chloromethylstyrene (CMS-14 available from AGC SEIMI CHEMICAL CO., LTD.) and bismuthiol. 60 parts of M-1 and 40 parts of methacrylic acid were added to 170 parts of ethanol and 30 parts of distilled water, and 62 parts of dimethylaminoethanol was added to the mixture to uniformly dissolve the same. Under nitrogen atmosphere, the mixture was transferred onto the water bath heated at 75° C., 5 parts of 3-mercaptopropyl(dimethoxy)methylsilane was added to the mixture, and 1 part of azobisisobutyronitrile (AIBN) was immediately added to the mixture as a polymerization initiator to start the polymerization. A mol % of the mercapto compound based on the whole monomer in this case was 4.0%. The mixture was stirred at an inner temperature of 73° C. for 10 hours, and then, cooled to room temperature. Distilled water was added to make up the whole amount 1 liter, and 1 part of Cupferron (N-nitrosophenylhydroxylamine ammonium salt) was added to the mixture as a polymerization inhibitor, and 35 parts of p-chloromethylstyrene (CMS-14 available from AGC SEIMI CHEMICAL CO., LTD.) was further added to the mixture, and the resulting mixture was stirred at 40° C. for 5 hours. Hydrochloric acid was gradually added to the mixture under ice-cooling to lower the pH of the same to 2, and the precipitated sediments were separated by filtration. The sediments were washed with distilled water and dried in a vacuum dryer to obtain a polymer having a structure shown by AP-4.

### Synthetic Example 2

### Synthetic Example of Polymer SP-2

To 300 parts of ethanol were added 10 parts of 3-mercaptopropyl(dimethoxy)-methylsilane, and then, 50 parts of distilled water, 50 parts of allyl methacrylate, 40 parts of acrylamide-2-methylpropanesulfonic acid and 7.7 parts of sodium hydroxide were added to the mixture to dissolve these materials. A mol % of the mercapto compound based on the whole monomer in this case was 9.3%. The mixture was heated at 70° C. and polymerized by adding 2 parts of azobisisobutyronitrile (AIBN) as a polymerization initiator under nitrogen atmosphere. The mixture was stirred at 70° C. for 6 hours to obtain a polymer solution having an estimated structure of SP-2.

### Synthetic Example 3

### Synthetic Example of Polymer SP-6

To a mixed solvent comprising 170 parts of ethanol and 30 parts of distilled water were added 47 parts of M-1 obtained in Synthetic example 1, 60 parts of acrylamide-2-methylpropanesulfonic acid and 78 parts of dimethylaminoethanol, and the mixture was uniformly dissolved. The mixture was transferred onto a water bath heated at 75° C. under nitrogen atmosphere, 5 parts of 3-mercaptopropyl(trimethoxy)-silane was added to the mixture, and 1 part of azobisisobutyronitrile (AIBN) was immediately added as a polymerization initiator to the mixture to start the polymerization. A mol % of the mercapto compound based on the whole monomer in this case was 5.5%. The mixture was stirred at an inner temperature of 73° C. for 10 hours and then cooled to room temperature. To the mixture was added 1 part of Cupferron (N-nitrosophenylhydroxylamine ammonium salt) as a polymerization inhibitor, and 35 parts of p-chloromethylstyrene (CMS-14 available from AGC SEIMI CHEMICAL CO., LTD.) was further added to the mixture and the resulting mixture was stirred at 40° C. for 5 hours. After the reaction, whole material was transferred into a large amount of ethyl acetate, and the precipitated polymer was washed with acetone and dried in vacuum. Thus, a polymer having an estimated structure SP-6 was obtained.

### Synthetic Example 4

### Synthetic Example of Polymer Grafted to Polyorganosiloxane Skeleton

(First Step) Synthesis of Polyorganosiloxane in which Mercapto Group is Introduced into the Side Chain

5 parts of 3-mercaptopropyl(dimethoxy)methylsilane and 25 parts of dimethyldimethoxysilane were mixed, 0.1N nitric acid was added to the mixture and the mixture was stirred at room temperature to carry out hydrolysis. Thereafter, methyl isobutyl ketone (MIBK) and sodium carbonate aqueous solution were added to the mixture to react them at room temperature for 20 hours to carry out polycondensation reaction. After neutralizing the mixture with dil. hydrochloric acid, the organic phase was separated and MIBK was distilled under reduced pressure to obtain a polyorganosiloxane in which mercapto groups had been introduced into the side chain. A molecular weight of the product was measured by using GPC and tetrahydrofuran (THF) as a solvent, and the weight average molecular weight of the product was about 5000 in terms of polystyrene.

### (Second Step) Synthesis of Precursor Polymer Graft-Polymerized to Polyorganosiloxane

In 300 parts of ethanol was dissolved 30 parts of the polyorganosiloxane synthesized above, then, 30 parts of p-chloromethylstyrene (CMS-14 available from AGC SEIMI CHEMICAL CO., LTD.), 70 parts of acrylamide-2-methylpropanesulfonic acid (ATBS available from TOAGOSEI CO., LTD.) and 52 parts of dimethylaminoethanol were added to the mixture and dissolved. The mixture was heated to 70° C., and 1 part of azobisisobutyronitrile (AIBN) was added to the mixture as a polymerization initiator under nitrogen atmosphere to carry out polymerization. The mixture was stirred at 70° C. for 6 hours to obtain a precursor polymer graft-polymerized to the polyorganosiloxane. A molecular weight of the obtained precursor polymer was measured by an aqueous GPC. As a result, a weight average molecular weight of said precursor polymer graft-polymerized was about 50,000. In this Synthetic example, the total amount of the silane compound used for synthesis of the polyorganosiloxane was 0.236 mol %, and a ratio thereof based on the whole monomer used for the graft polymerization was 44 mol %.

### (Synthesis of Mercaptomethylstyrene)

In 100 parts of ethanol and 500 parts of distilled water was dissolved 153 parts of p-chloromethylstyrene (CMS-14 available from AGC SEIMI CHEMICAL CO., LTD.), and 101 parts of triethylamine was gradually added to the mixture while cooling the mixture in an ice-bath. While maintaining the inner temperature to 0 to 5° C., 76 parts of thioacetic acid was added dropwise to the mixture over 1 hour. The mixture was stirred at room temperature for 3 hours, 500 parts of ethyl acetate was added to the mixture, and the organic phase was washed with water and evaporated. The resulting colorless oil was added to markedly excess amount of aqueous ammonia, and the mixture was heated at 70° C. for 1 hour and extracted again with ethyl acetate. The organic phase was washed with water and evaporated to obtain the objective mercaptomethylstyrene.

### (Third Step) Synthesis of Polymer of the Present Invention

To whole precursor polymer solution obtained by the previous Second step was added 30 parts of mercaptomethylstyrene synthesized as mentioned above, and 1 part of Cupferron (N-nitrosophenylhydroxylamine ammonium salt) was added to the mixture as a polymerization inhibitor, and the resulting mixture was stirred at 70° C. for 5 hours on a heated water bath. After cooling the mixture to room temperature, whole material was transferred into ethyl acetate, and the precipitated polymer was filtered and dried. According to analysis of the product by GPC, a weight average molecular weight was about 70,000. As a result of structure analysis by proton NMR, the presence of the polymerizable double bond and the presence of the polyorganosiloxane structural unit were confirmed. Thus, it was found that the structure had not been contradictory to the following mentioned structure as an estimated structure, whereby the objective polymer of the present invention could be obtained. In the formula, the numerals represent parts by weight.

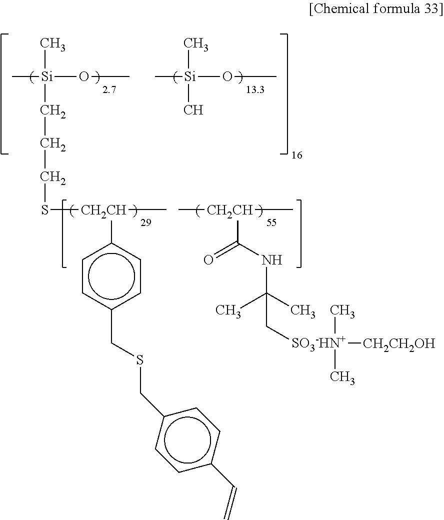

### Comparative Synthetic Example 1

Synthesis of a comparative polymer having no polyorganosiloxane structural unit is carried out. That is, 30 parts of p-chloromethylstyrene (CMS-14 available from AGC SEIMI CHEMICAL CO., LTD.), 70 parts of acrylamide-2-methylpropanesulfonic acid (ATBS available from TOAGOSEI CO., LTD.) and 52 parts of dimethylaminoethanol were charged and dissolved. Heating was carried out at 70° C., and under nitrogen atmosphere, 1 part of azobisisobutyronitrile (AIBN) was added to the mixture as a polymerization initiator to carry out polymerization. The mixture was stirred at 70° C. for 6 hours to obtain a polymer. To the obtained polymer solution was added 30 parts of mercaptomethylstyrene, and 1 part of Cupferron (N-nitrosophenylhydroxylamine ammonium salt) was added to the mixture as a polymerization inhibitor, and the mixture was stirred on a heated water bath at 70° C. for 5 hours. After cooling the mixture to room temperature, whole material was transferred into ethyl acetate, and the precipitated polymer was filtered and dried. According to analysis of the product by GPC, the weight average molecular weight thereof was about 90,000, and as a result of structural analysis by proton NMR, presence of the polymerizable double bond was confirmed. Thus, it could be found that the structure had not been contradictory to the following mentioned structure as an estimated structure.

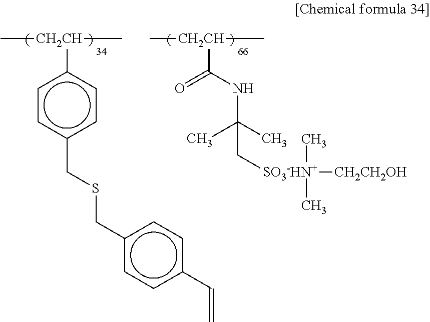

### Synthetic Example 5

### Synthetic Example of a Polymer Grafted to Polyorganosiloxane Skeleton

(First Step) Synthesis of Polyorganosiloxane in which a Mercapto Group is Introduced into the Side Chain

15 parts of 3-mercaptopropyl(dimethoxy)methylsilane and 25 parts of dimethyldimethoxysilane were mixed, and 0.1N nitric acid was added to the mixture. The resulting mixture was mixed at room temperature under stirring to carry out hydrolysis, then, methyl isobutyl ketone (MIBK) and sodium carbonate aqueous solution were added to the mixture and reacted at room temperature for 20 hours to carry out polycondensation reaction. After neutralizing with dil. hydrochloric acid, the organic phase was separated and MIBK was distilled under reduced pressure to obtain a polyorganosiloxane in which mercapto groups had been introduced into the side chain. A molecular weight of the produce was measured by GPC using tetrahydrofuran (THF) as a solvent, and it had a weight average molecular weight of about 7000 in terms of polystyrene.

### (Second Step) Synthesis of Precursor Polymer Graft-Polymerized to Polyorganosiloxane

40 parts of the polyorganosiloxane synthesized as mentioned above was suspended in 350 parts of ethanol and 50 parts of distilled water, then, 80 parts of M-1 obtained in Synthetic example 1, as well as 120 parts of acrylamide-2-methylpropanesulfonic acid and 79 parts of dimethylaminoethanol were added to the dispersion to dissolve the mixture. The mixture was heated at 70° C., and under nitrogen atmosphere, 2 parts of azobisisobutyronitrile (AIBN) was added to the mixture as a polymerization initiator to carry out polymerization. The mixture was stirred at 70° C. for 6 hours to obtain a precursor polymer graft-polymerized to the polyorganosiloxane. The obtained precursor polymer was carried out measurement of the molecular weight by aqueous GPC. As a result, the weight average molecular weight of the graft-polymerized precursor polymer was about 100,000. In this synthetic example, total amount of the silane compound used for synthesis of the polyorganosiloxane was 0.29 mol %, and a ratio thereof to the whole monomer used for the graft polymerization was 33 mol %.

### (Third Step) Synthesis of Polymer of the Present Invention

To the whole precursor polymer solution obtained in the previous Second step was added 46 parts of p-chloromethylstyrene, 1 part of Cupferron (N-nitrosophenyl-hydroxylamine ammonium salt) was added to the mixture as a polymerization inhibitor, and the mixture was stirred on a water bath heated at 50° C. for 5 hours. After cooling to room temperature, the whole material was transferred into ethyl acetate, and the precipitated polymer was filtered and dried. According to analysis of the product by GPC, the weight average molecular weight was about 70,000, and as a result of structural analysis by proton NMR, presences of the polymerizable double bond and the polyorganosiloxane structural unit were confirmed. Thus, it could be found that the structure had not been contradictory to the following mentioned structure as an estimated structure, whereby the objective polymer of the present invention could be obtained. In the formula, the numerals represent parts by weight.

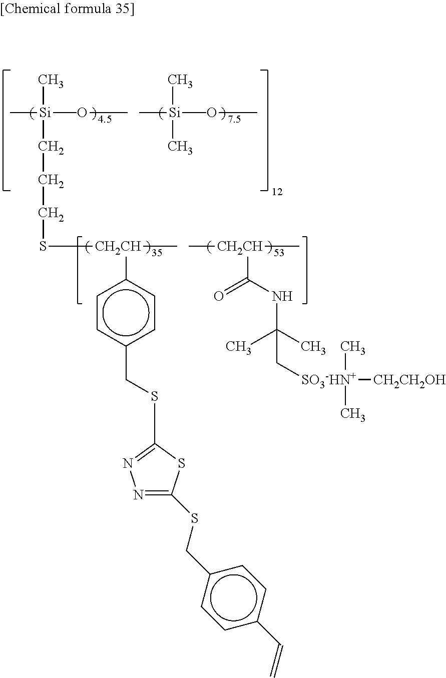

### Synthetic Example 6

### Synthetic Example of Polymer Grafted to Polyorganosiloxane Skeleton

20 parts of 3-mercaptopropyltrimethoxysilane was dissolved in 350 parts of ethanol and 50 parts of distilled water. To the solution was added 80 parts of M-1 obtained in the previous Synthetic example 1, then, 120 parts of acrylamide-2-methyl-propanesulfonic acid and 80 parts of dimethylaminoethanol were further added, and, under a nitrogen atmosphere, whole material was heated at 70° C. to dissolve the compounds. A mol % of the mercapto compound based on the whole monomer in this case was 11%. 2 parts of AIBN was added to the mixture as a polymerization initiator to initiate polymerization, and the mixture was stirred at 70° C. for 10 hours. The whole material was cooled to 50° C., 1 part of Cupferron was added thereto as a polymerization inhibitor, and 46 parts of p-chloromethylstyrene was further added to the mixture and the resulting mixture was stirred at the same temperature for 5 hours. Thereafter, the mixture was cooled to room temperature, and the precipitated sediments were separated by decantation, washed sufficiently with methanol and then dried. A white colored polymer was obtained with yield of 80%. From GPC measurement, it could be obtained a weight average molecular weight calculated on polystyrene of 150,000, and from proton NMR measurement, a result which does not inconsistent with the structure shown by the following mentioned formula could be obtained. In the formula, the numerals represent parts by weight.

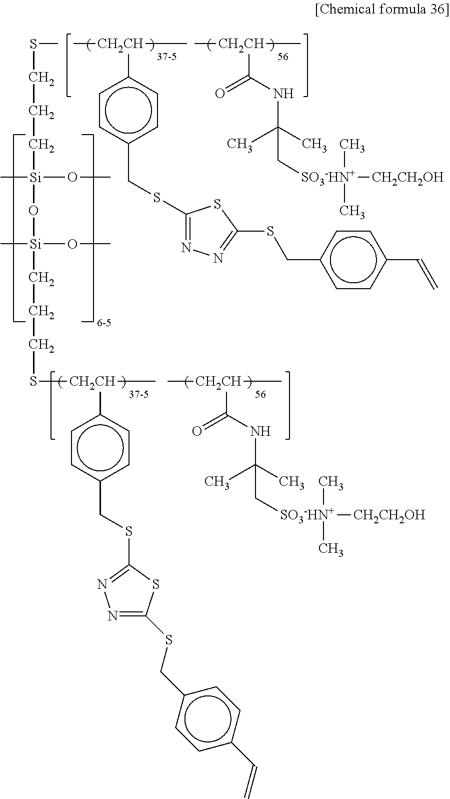

### Synthetic Example 7

### Synthetic Example of Polymer Grafted to Polyorganosiloxane Skeleton

(1st Step) Synthesis of Polyorganosiloxane in which a Mercapto Group is Introduced into the Side Chain

5 parts of 3-mercaptopropyl(dimethoxy)methylsilane and 25 parts of dimethyldimethoxysilane were mixed, 0.1N nitric acid was added and the mixture was stirred at room temperature to carry out hydrolysis. Then, methyl isobutyl ketone (MIBK) and sodium carbonate aqueous solution were added to the mixture, and the resulting mixture was reacted at room temperature for 20 hours to carry out polycondensation reaction. After neutralizing the mixture with dil. hydrochloric acid, the organic phase was separated and MIBK was distilled off under reduced pressure to obtain a polyorganosiloxane in which mercapto groups had been introduced into the side chain. A molecular weight of the product was measured by using GPC and tetrahydrofuran (THF) as a solvent, then, it had a weight average molecular weight calculated on polystyrene of about 5000.

### (2nd Step) Synthesis of Precursor Polymer Graft-Polymerized to Polyorganosiloxane

In 300 parts of ethanol was dissolved 30 parts of the polyorganosiloxane synthesized as mentioned above, and 60 parts of M-1 obtained in Synthetic example 1 and 40 parts of methacrylic acid were added to the mixture in combination with 30 parts of distilled water, and then, 62 parts of dimethylaminoethanol was added to the mixture and the resulting mixture was uniformly dissolved. The mixture was heated to 70° C., and 1 part of azobisisobutyronitrile (AIBN) was added to the mixture as a polymerization initiator under nitrogen atmosphere to carry out polymerization. The mixture was stirred at 70° C. for 10 hours, a precursor polymer graft-polymerized to the polyorganosiloxane was obtained. In this Synthetic example, the total amount of the silane compound used for synthesis of the polyorganosiloxane was 0.236 mol %, and a ratio based on the whole monomer used for graft polymerization was 34 mol %.

### (3rd Step) Synthesis of Polymer of the Present Invention

To the whole precursor polymer solution obtained in the prior Second step was added 35 parts of p-chloromethylstyrene (CMS-14 available from AGC SEIMI CHEMICAL CO., LTD.), and the mixture was stirred at 40° C. for 5 hours. Hydrochloric acid was gradually added under ice-cooling to lower the pH of the reaction system to 2, and the precipitated sediments were separated by filtration. The sediments were washed with distilled water and dried in a vacuum dryer to obtain a polymer of the present invention having a structure shown in the following estimated chemical formula. In the formula, the numerals represent parts by weight.

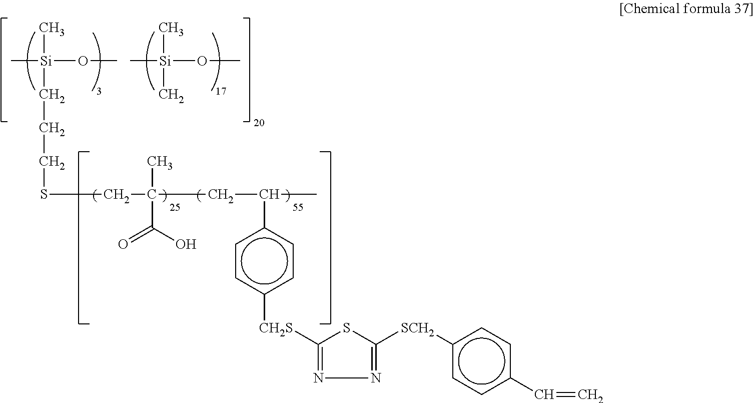

### Comparative Synthetic Example 2

Synthesis of Comparative polymer having no polyorganosiloxane structural unit was carried out. 80 parts of M-1 was charged, then, 120 parts of acrylamide-2-methylpropanesulfonic acid and 80 parts of dimethylaminoethanol were added thereto, and the whole mixture was heated to 70° C. under a nitrogen atmosphere to dissolve the same. As a polymerization initiator, 2 parts of AIBN was added to the solution to initiate polymerization, and the mixture was stirred at 70° C. for 10 hours. The whole part was cooled to 50° C., 1 part of Cupferron was added thereto as a polymerization inhibitor, and further 46 parts of p-chloromethylstyrene was added to the mixture and the resulting mixture was stirred at the same temperature for 5 hours. Thereafter, the mixture was cooled to room temperature, and the precipitated sediments were separated by decantation, washed sufficiently with methanol and then dried. A white-colored polymer was obtained with yield of 80%. From GPC measurement, it could be obtained a weight average molecular weight calculated on polystyrene of 150,000, and from proton NMR measurement, a result which does not inconsistent with the structure shown by the following mentioned formula could be obtained. In the formula, the numerals represent parts by weight.

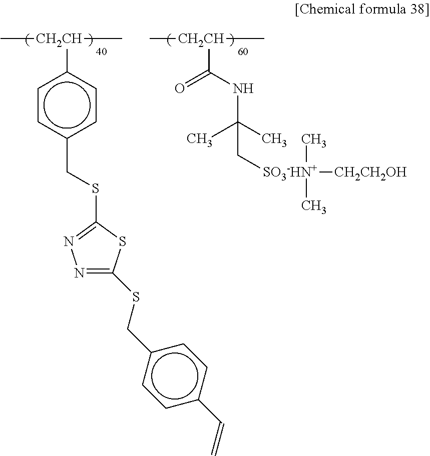

### Comparative Synthetic Example 3

Synthesis of a comparative polymer having no polyorganosiloxane structural unit was carried out. To a mixed solvent of 150 parts of ethanol and 30 parts of distilled water was added 60 parts of M-1, then, further 40 parts of methacrylic acid and 62 parts of dimethylaminoethanol were added to the mixture, and under a nitrogen atmosphere, the whole mixture was heated at 70° C. to dissolve the components. To the mixture was added 1 part of AIBN as a polymerization initiator to initiate polymerization, and the mixture was stirred at 70° C. for 10 hours. The whole mixture was cooled to 50° C., 1 part of Cupferron was added to the mixture as a polymerization inhibitor, further 46 parts of p-chloromethylstyrene was added to the same and the mixture was stirred at the same temperature for 5 hours. Thereafter, the mixture was cooled to room temperature, and the precipitated sediments were separated by decantation, washed sufficiently with methanol and then dried. A white colored polymer was obtained with yield of 70%. From GPC measurement, it could be obtained a weight average molecular weight calculated on polystyrene of 100,000, and from proton NMR measurement, a result which does not inconsistent with the structure shown by the following mentioned formula could be obtained. In the formula, the numerals represent parts by weight.

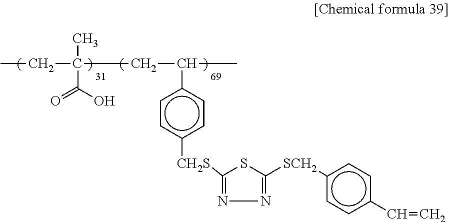

### Light-Sensitive Lithographic Printing Plate Materials of Examples 1 to 4 and Comparative Examples 1 to 4

An aluminum plate in which an anodized aluminum plate having a thickness of 0.24 mm which had been carried out a sand-grained treatment was further subjected to silicate treatment using sodium silicate was used as a support. By using the polymers of the present invention obtained in Synthetic example 2 and Synthetic examples 4 to 6, each coating solution having the following mentioned photo-curable light-sensitive layer prescription was prepared, and coated on said aluminum plate and dried to form a photo-curable light-sensitive layer, whereby each of the light-sensitive lithographic printing plate materials of Examples 1 to 4 was prepared. Coating was so carried out that a coating amount of the photo-curable light-sensitive layer became 1.6 g per 1 m² in a dry weight by using a wire bar. Drying was carried out in a dryer at 80° C. for 10 minutes.

### (Prescription of Photo-Curable Light-Sensitive Layer 1)

| | | |
|---|---|---|
| Polymer | 1 | part |
| Photopolymerization initiator (BC-6) | 0.1 | part |
| Photopolymerization initiator (T-4) | 0.06 | part |
| Sensitizing dye (S-38) | 0.03 | part |
| Victoria blue (dye for coloring) | 0.02 | part |
| Distilled water | 4 | parts |
| Dioxane | 5 | parts |
| Ethanol | 1 | part |

By using the polymer obtained in Comparative synthetic examples 1 and 2, light-sensitive lithographic printing plate materials of Comparative examples 1 and 2 were similarly prepared by using the above-mentioned photo-curable light-sensitive layer prescription. Further, as a comparison, by using a compound commercially available from Shin-etsu Chemical Co., Ltd, under trade name of “X-22-164A” as a polyorganosiloxane having a structure in which methacryloyl groups are bonded at the both ends of the polydimethylsiloxane as a polymerizable double bond, said compound was further added to the photo-curable light-sensitive layer prescription of Comparative examples 1 and 2 in an amount of 0.3 part whereby light-sensitive lithographic printing plate materials of Comparative examples 3 and 4 were prepared. These Comparative examples 3 and 4 were prepared so as to compare the effect in which the polyorganosiloxane is blended with the case of the graft polymer (Examples 2 to 4).

### (Exposure Test)

The light-sensitive lithographic printing plate materials prepared as mentioned above was subjected to exposure test as follows. Exposure was carried out by using PT-R4000 (manufactured by DAINIPPON SCREEN MFG. CO., LTD.) mounting a laser having a light wavelength of 830 nm, setting an exposure energy to 100 mJ/cm² using the device, with a drum rotation number of 1,000 rpm. As an image for the test, halftone gradation pattern showing dot area from 1% to 97% corresponding to 2400 dpi and 175 lines; fine lines of 10 to 100 μm; and solid image were output to carry out evaluation of the following mentioned resolution.

### (Water Developability Test)

Each light-sensitive lithographic printing plate subjected to drawing as mentioned above was immersed in water controlled to 30° C. for 10 seconds, and the surface was rubbed by a sponge softly to remove the unexposed portion. At this time, as developability evaluation, the case where the unexposed portion was completely removed was judged as ◯, the case where a remaining film was slightly admitted at the unexposed portion was judged as Δ, and the case where developability was poor and a remaining film or developing failure was clearly caused was judged as X. Moreover, resolution was evaluated, and the case where 10 μm fine lines and 1% halftone dots were clearly reproduced was judged as ◯, the case where they were partially omitted but 20 μm or more of fine lines and 2% or more of halftone dots were clearly reproduced was judged as Δ, and the case where the reproducibility lower than the above was judged as X. The results are summarized in Table 1.

TABLE 1

| | Example 1 | Example 2 | Example 3 | Example 4 |
|---|---|---|---|---|
| Water | ◯ | ◯ | ◯ | ◯ |
| developability | | | | |
| Resolution | Δ | ◯ | ◯ | ◯ |
| | Comparative | Comparative | Comparative | Comparative |
| | example 1 | example 2 | example 3 | example 4 |
| Water | ◯ | ◯ | X | X |
| developability | | | | |
| Resolution | ◯ | ◯ | Δ | Δ |

### (Printability Test)

By using the developed samples as mentioned above, usual offset printing was carried out by using Ryobi 560 as a printer, black ink for offset printing as printing ink, and 1% aqueous solution of a dampening solution Aquaunity WKK for offset printing available from Toyo Ink Co., Ltd. as a dampening solution. As printing evaluations, with regard to printing endurance, the case where 20 μm fine lines and dot area of 2% fine halftone dot portion were reproduced on the printed material with each 10,000 sheets from starting the printing was judged as ◯, the case where they were partially omitted was judged as Δ, and the case where they were substantially completely omitted was judged as X. As an index of ink transfer property, abrasion resistance was evaluated. With regard to the abrasion resistance, the ink on the printing plate was wiped off with a cleaner solution each 10,000 sheets from starting the printing, and then, reflection density at the solid portion in the test image was measured by using a reflection densitometer DM-620 manufactured by DAINIPPON SCREEN MFG. CO., LTD., and it was evaluated by observing lowering in reflection density during the printing. The results are summarized in Table 2.

TABLE 2

| | Example 1 | Example 2 | Example 3 | Example 4 |
|---|---|---|---|---|
| Reflection | | | | |
| density | | | | |
| Start | 1.6 | 1.6 | 1.6 | 1.6 |
| 10,000 sheets | 1.2 | 1.4 | 1.5 | 1.6 |
| 20,000 sheets | 1.0 | 1.3 | 1.5 | 1.6 |
| 30,000 sheets | 0.9 | 1.1 | 1.4 | 1.5 |
| 40,000 sheets | 0.8 | 1.0 | 1.4 | 1.4 |
| 50,000 sheets | 0.7 | 0.9 | 1.4 | 1.4 |
| Printing | | | | |
| endurance | | | | |
| Start | ◯ | ◯ | ◯ | ◯ |
| 10,000 sheets | ◯ | ◯ | ◯ | ◯ |
| 20,000 sheets | ◯ | ◯ | ◯ | ◯ |
| 30,000 sheets | ◯ | ◯ | ◯ | ◯ |
| 40,000 sheets | Δ | ◯ | ◯ | ◯ |
| 50,000 sheets | Δ | ◯ | ◯ | ◯ |
| | Comparative | Comparative | Comparative | Comparative |
| | example 1 | example 2 | example 3 | example 4 |
| Reflection | | | | |
| density | | | | |
| Start | 1.6 | 1.6 | 1.6 | 1.6 |
| 10,000 sheets | 1.2 | 1.2 | 1.1 | 1.4 |
| 20,000 sheets | 0.8 | 1.1 | 0.8 | 1.1 |
| 30,000 sheets | 0.5 | 0.7 | 0.5 | 0.8 |
| 40,000 sheets | 0.3 | 0.6 | 0.4 | 0.5 |
| 50,000 sheets | 0.2 | 0.5 | 0.3 | 0.3 |
| Printing | | | | |
| endurance | | | | |
| Start | ◯ | ◯ | Δ | Δ |
| 10,000 sheets | Δ | Δ | Δ | Δ |
| 20,000 sheets | X | Δ | Δ | Δ |
| 30,000 sheets | X | Δ | X | Δ |
| 40,000 sheets | X | X | X | X |
| 50,000 sheets | X | X | X | X |

When the light-sensitive lithographic printing plates of Examples 1 to 4 of the present invention are used, good printed materials could be obtained with regard to ink transfer property even when 50,000 sheets of printing had been carried out, and change in reflection density at the image portion on the printing plate was a little. Also, there is no occurrence of background stain and good results could be obtained. In Comparative examples 1 and 2, remarkable lowering in reflection density at the image portion of the printed material has already generated with the printing of 40,000 sheets, and failure of ink transfer was partially generated. In Comparative examples 3 and 4, background stain on the printed material was remarkable, printing endurance was poor, and further lowering in reflection density at the image portion of the printing plate was remarkable.

### Light-Sensitive Lithographic Printing Plate Material of Examples 5 to 8 and Comparative Examples 5 and 6

By using a polyester film having a thickness of 175 μm, on the surface thereof was coated, as a hydrophilic layer described in JP 2008-250195A, the following mentioned hydrophilic layer coating solution prescription so that a dry weight thereof became 3 g per 1 m² using a wire bar. Drying was carried out by using a dryer at 80° C. for 20 minutes. The sample was further heated in a dryer at 40° C. for 3 days, and then, applied to the subsequent coating of the photo-curable light-sensitive layer.

### (Prescription of Hydrophilic Layer Coating Solution)

| | |
|---|---|
| Polyacrylamide-acrylic acid (80/20) copolymer 10% aqueous | 100 parts |
| solution | |
| Colloidal silica (Snowtex PS-S available from Nissan | 100 parts |
| Chemical Co., Ltd.) (20% concentration) | |
| Epoxy cross-linking agent (DENACOL EX-512 available | 2 parts |
| from NAGASE & CO., LTD.) raw solution | |
| Distilled water | 100 parts |

By using the polymers of the present invention obtained in Synthetic example 2 and Synthetic examples 4 to 6, a coating solution of the following mentioned photocurable light-sensitive layer prescription 2 was prepared, and coated on the above-mentioned hydrophilic layer and dried to for a photo-curable light-sensitive layer, to prepare each light-sensitive lithographic printing plate material of Examples 5 to 8. A coated amount of the photo-curable light-sensitive layer was so set to become 1.6 g per 1 m² in a dry weight by using a wire bar. Drying was carried out by using a dryer at 80° C. for 10 minutes. Further, on the photo-curable light-sensitive layer, by using a polyvinyl alcohol (PVA-105 available from KURARAY CO., LTD.) as a protective layer, coating was carried out so that a dry coated weight became 2.0 g per 1 m² by using a wire bar. Drying was carried out by using a dryer at 80° C. for 10 minutes.

### (Photo-Curable Light-Sensitive Layer Prescription 2)

| | | |
|---|---|---|
| Polymer | 1 | part |
| Photopolymerization initiator (BC-6) | 0.1 | part |
| Photopolymerization initiator (T-6) | 0.06 | part |
| Sensitizing dye (S-11) | 0.03 | part |
| Phthalocyanine Blue(coloring pigment) | 0.02 | part |
| Distilled water | 4 | parts |
| Dioxane | 5 | parts |
| Ethanol | 1 | part |

Completely the same manner, using the polymer obtained in Comparative synthetic examples 1 and 2, light-sensitive lithographic printing plate materials of Comparative examples 5 and 6 were prepared by using the above-mentioned photocurable light-sensitive layer prescription and protective layer.

### (Exposure Test)

The light-sensitive lithographic printing plate materials prepared as mentioned above was subjected to exposure test as follows. Exposure was carried out by using an image setter VIPLAS (manufactured by Mitsubishi Paper Mills Limited) for CTP mounted thereon a semiconductor laser with a light wavelength of 405 nm, setting an exposure energy on the plate surface to 80 mJ/cm² using the device, and image drawing was carried out by the scanning exposure system. As an image for the test, halftone gradation pattern showing dot area from 1% to 97% corresponding to 2400 dpi and 175 lines; fine lines of 10 to 100 min; and solid image were output to carry out evaluation of the following mentioned resolution.

### (Water Developability Test)

Each light-sensitive lithographic printing plate subjected to drawing as mentioned above was immersed in water controlled to 30° C. for 10 seconds, and the surface was rubbed by a sponge softly to remove the unexposed portion. At this time, as developability evaluation, the case where the unexposed portion was completely removed was judged as ◯, the case where a remaining light-sensitive layer was slightly admitted was judged as Δ, and the case where developability was poor and a remaining film or developing failure was clearly caused was judged as X. Moreover, resolution was evaluated, and the case where 10 μm fine lines and 1% halftone dots were clearly reproduced was judged as ◯, the case where they were partially omitted but 20 μm or more of fine lines and 2% or more of halftone dots were clearly reproduced was judged as Δ, and the case where the reproducibility lower than the above was judged as X. The results are summarized in Table 3.

TABLE 3

| | | | | | Compar- | Compar- |
|---|---|---|---|---|---|---|
| | | | | | ative | ative |
| | Exam- | Exam- | Exam- | Exam- | example | example |
| | ple 5 | ple 6 | ple 7 | ple 8 | 5 | 6 |
| Water de- | ◯ | ◯ | ◯ | ◯ | ◯ | ◯ |
| velopability | | | | | | |
| Resolution | Δ | Δ | ◯ | ◯ | X | Δ |

### (Printability Test)

By using the developed samples as mentioned above, usual off-set printing was carried out by using Ryobi 560 as a printer, black ink for offset printing as printing ink, and 1% aqueous solution of a dampening solution Aquaunity WKK for offset printing available from Toyo Ink Co., Ltd. as a dampening solution. As printing evaluations, with regard to printing endurance, the case where 20 μm fine lines and dot area of 2% fine halftone dot portion were reproduced on the printed material with each 10,000 sheets from starting the printing was judged as ◯, the case where they were partially omitted was judged as Δ, and the case where they were substantially completely omitted was judged as X. As an index of the ink transfer property, abrasion resistance was evaluated. With regard to the abrasion resistance, the ink on the printing plate was wiped off with a cleaner solution each 10,000 sheets from starting the printing, and then, reflection density at the solid portion in the test image was measured by using a reflection densitometer DM-620 manufactured by DAINIPPON SCREEN MFG. CO., LTD., and it was evaluated by observing lowering in reflection density during printing. The results are summarized in Table 4.

TABLE 4

| | | | | | Compar- | Compar- |
|---|---|---|---|---|---|---|
| | Example | Example | Example | Example | ative | ative |
| | 5 | 6 | 7 | 8 | example 5 | example 6 |
| Reflection | | | | | | |
| density | | | | | | |
| Start | 1.6 | 1.6 | 1.6 | 1.6 | 1.6 | 1.6 |
| 5000 | 1.2 | 1.4 | 1.5 | 1.6 | 1.2 | 1.2 |
| sheets | | | | | | |
| 10,000 | 1.0 | 1.3 | 1.5 | 1.6 | 0.8 | 0.8 |
| sheets | | | | | | |
| 15,000 | 0.8 | 1.1 | 1.4 | 1.5 | 0.5 | 0.7 |
| sheets | | | | | | |
| 20,000 | 0.7 | 0.9 | 1.2 | 1.4 | 0.3 | 0.5 |
| sheets | | | | | | |
| Printing | | | | | | |
| endurance | | | | | | |
| Start | ◯ | ◯ | ◯ | ◯ | ◯ | ◯ |
| 5000 | ◯ | ◯ | ◯ | ◯ | Δ | Δ |
| sheets | | | | | | |
| 10,000 | ◯ | ◯ | ◯ | ◯ | X | Δ |
| sheets | | | | | | |
| 15,000 | Δ | ◯ | ◯ | ◯ | X | Δ |
| sheets | | | | | | |
| 20,000 | Δ | ◯ | ◯ | ◯ | X | X |
| sheets | | | | | | |

When light-sensitive lithographic printing plates of Examples 5 to 8 of the present invention are used, good printed materials could be obtained with regard to ink transfer property even when 20,000 sheets of printing had been carried out, and change in reflection density at the image portion on the printing plate was a little. Also, there is no occurrence of background stain and good results could be obtained. In Comparative examples 5 and 6, remarkable lowering in reflection density at the image portion of the printed material has already generated with the printing of 10,000 sheets, and failure of ink transfer was partially generated.

### Examples 9 to 11 and Comparative Example 7

### Example and Comparative Example of Light-Sensitive Lithographic Printing Plate Materials

An aluminum plate in which an anodized aluminum plate having a thickness of 0.24 mm which had been carried out a sand-grained treatment was further subjected to silicate treatment using sodium silicate was used as a support. By using the polymers shown in Table 5 were used as a polymer, coating solutions with the following mentioned photo-curable light-sensitive layer prescription 3 were prepared, and each solution was coated on said aluminum plate and dried to prepare light-sensitive lithographic printing plate materials of Examples 9 to 11. AP-2 used in Example 9 was synthesized by polymerizing 65 parts of allyl methacrylate and 35 parts of acrylic acid in the presence of 7 parts of trimethoxy silane according to the conventionally known method. As Comparative example 7, a coating solution with the photo-curable light-sensitive layer prescription 3 was simultaneously prepared in the same manner as mentioned above by using the polymer obtained in Comparative synthetic example 3, and the solution was coated on said aluminum plate and dried to prepare a comparative light-sensitive lithographic printing plate material of Comparative example 7. A coated amount of the photo-curable light-sensitive layer was so set and coated to be 1.8 g per 1 m² with a dry weight by using a wire bar. Drying was carried out by using a dryer at 80° C. for 10 minutes. Further, on these photo-curable light-sensitive layers, as a protective layer, by using a polyvinyl alcohol (PVA-105 available from KURARAY CO., LTD.), it was coated so that a dry coated weight became 2.0 g per 1 m² by using a wire bar. Drying was carried out by using a dryer at 80° C. for 10 minutes.

### (Photo-Curable Light-Sensitive Layer Prescription 3)

| | | |
|---|---|---|
| Polymer (Table 5) | 1.10 | parts |
| Trimethylolpropane triacrylate | 0.40 | part |
| Organic boron salt compound (BC-6) | 0.20 | part |
| Trihaloalkyl-substituted compound (T-6) | 0.15 | part |
| Sensitizing dye (S-3) | 0.04 | part |
| Phthalocyanine Blue (coloring pigment) | 0.05 | part |
| N-nitrosophenylhydroxylamine aluminum salt | 0.02 | part |
| Dioxane | 20 | parts |
| Ethanol | 5 | parts |

TABLE 5

| | Polymer |
|---|---|
| Example 9 | AP-2 |
| Example 10 | AP-4 |
| Example 11 | Synthetic example 7 |
| Comparative | Comparative synthetic |
| example 7 | example 3 |

### (Exposure Test)

The light-sensitive lithographic printing plate materials prepared as mentioned above was subjected to exposure test as follows. Exposure was carried out by using an image setter VIPLAS (manufactured by Mitsubishi Paper Mills Limited) for CTP mounted thereon a semiconductor laser with a light wavelength of 405 nm, setting an exposure energy on the plate surface to 120 μJ/cm² using the device, and image drawing was carried out by the scanning exposure system. As an image for the test, halftone gradation pattern from 1% to 97% corresponding to 2400 dpi and 175 lines; fine lines of 10 to 100 μm were output. The exposed light-sensitive lithographic printing plate materials were subjected to development by using the developing solution prepared by the following mentioned constitution. Development was carried out by using an automatic developing device P-1310T manufactured by Mitsubishi Paper Mills Limited and treatment was carried out at 30° C. for 15 seconds.

### (Prescription of Developing Solution)

| | |
|---|---|
| Dimethylaminoethyl alcohol | 30 parts |
| Tetramethyl ammonium hydroxide | 15 parts |
| Sodium butylnaphthalene sulfonate | 10 parts |

Water was added so that the whole amount became 1000 parts, and a pH was adjusted to 11.0 by further adding 85% phosphoric acid.

### (Printability Evaluation)

By using the sample developed with the above-mentioned conditions at 30° C. for 15 seconds, usual off-set printing was carried out by using Ryobi 560 as a printer, black ink for offset printing as printing ink, and 1% aqueous solution of a dampening solution Aquaunity WKK for offset printing available from Toyo Ink Co., Ltd. as a dampening solution. As printing evaluations, with regard to printing endurance, the case where 20 μm fine lines and dot area of 2% fine halftone dot portion were reproduced on the printed material by 50,000 sheets from starting the printing was judged as ◯, the case where they were partially omitted was judged as Δ, and the case where they were substantially completely omitted was judged as X. Also, with regard to background stain property, by using both samples immediately after development and after plate preservation as mentioned below, the case where background stain was clearly generated on the printed material through the printing was judged as X, the case where it was slightly admitted was judged as Δ, and the case where no stain was admitted was judged as ◯. As a plate for placing, the sample after development was allowed to stand in a dryer heated to 50° C. for 48 hours was used as a sample and printability evaluation thereof was carried out. The results are summarized in Table 6.

TABLE 6

| | Printing | Background | Background stain |
|---|---|---|---|
| | endurance | stain | after placing plate |
| Example 9 | Δ | ◯ | Δ |
| Example 10 | ◯ | ◯ | ◯ |
| Example 11 | ◯ | ◯ | Δ |
| Comparative | ◯ | Δ | X |
| example 7 | | | |

From the above-mentioned results, with regard to the printing endurance, there is substantially no difference in the results of Examples 9 to 11 and Comparative example 7, but with regard to background stain and background stain after plate preservation, the obtained results show that Examples 9 to 11 are clearly excellent.

### Examples 12 to 15 and Comparative Example 8

### Examples and Comparative Example of Light-Sensitive Lithographic Printing Plate Materials

In the same manner as in the above-mentioned Examples 9 to 11 and Comparative example 7 except for using the polymer shown in Table 7 as a polymer, light-sensitive lithographic printing plate materials of Examples 12 to 15 and Comparative example 8 were prepared.

TABLE 7

| | Polymer |
|---|---|
| Example 12 | SP-2 |
| Example 13 | SP-5 |
| Example 14 | Synthetic example 4 |
| Example 15 | Synthetic example 6 |
| Comparative | Comparative synthetic |
| example 8 | example 2 |

By using the light-sensitive lithographic printing plate materials prepared as mentioned above, exposure was carried out in the same manner as in the above-mentioned Examples. Development was carried out by using distilled water, and the treatment was carried out at 30° C. for 15 seconds using an automatic developing device P-1310T manufactured by Mitsubishi Paper Mills Limited as a developing device. Evaluation of printability was carried out in the same manner as in the above-mentioned Examples, and printing endurance, background stain and background stain after plate preservation were evaluated. The results are summarized in Table 8.

TABLE 8

| | Printing | Background | Background stain |
|---|---|---|---|
| | endurance | stain | after placing plate |
| Example 12 | Δ | ◯ | ◯ |
| Example 13 | ◯ | ◯ | ◯ |
| Example 14 | ◯ | ◯ | Δ |
| Example 15 | ◯ | ◯ | ◯ |
| Comparative | ◯ | ◯ | X |
| example 8 | | | |

From the above-mentioned results, with regard to the printing endurance and background stain immediately after development, difference cannot substantially be admitted between Examples 12 to 15 and Comparative example 8, but with regard to background stain after plate preservation, the obtained results show that Examples 12 to 15 are clearly excellent.

### Examples 16 to 19 and Comparative Example 9

### Examples and Comparative Example of Light-Sensitive Lithographic Printing Plate Materials

By using a polyester film having a thickness of 175 μm, the following mentioned hydrophilic layer coating solution prescription was coated thereon as a hydrophilic layer described in JP 2008-250195A using a wire bar so that a dry weight became 3 g per 1 m². Drying was carried out in a dryer at 80° C. for 20 minutes. Each sample was further heated in a dryer at 40° C. for 3 days, and then, applied to the subsequent coating of a photo-curable light-sensitive layer.

### (Hydrophilic Layer Coating Solution Prescription)

| | |
|---|---|
| Polyacrylamide-acrylic acid (80/20) copolymer 10% aqueous | 100 parts |
| solution | |
| Colloidal silica (SNOWTEX PS-S, available from Nissan | 100 parts |
| Chemical Co., Ltd.) (20% concentration) | |
| Epoxy cross-linking agent (DENACOL EX-512, available | 2 parts |
| from NAGASE & CO., LTD.) raw solution | |
| Distilled water | 100 parts |

The following mentioned photo-curable light-sensitive layer prescription 4 was prepared by using the polymer shown in Table 9, and coated on the above-mentioned hydrophilic layer and dried to obtain each light-sensitive lithographic printing plate material of Examples 16 to 19. In Comparative example 9, a coating solution for the photo-curable light-sensitive layer prescription was prepared in the same manner by using the polymer obtained in Comparative synthetic example 2 as a polymer, and coated on said hydrophilic layer, and dried to obtain Comparative light-sensitive lithographic printing plate material of Comparative example 9. A coated amount of the photo-curable light-sensitive layer was so provided by using a wire bar that it became 2.0 g per 1 m² as a dry weight. Drying was carried out in a dryer at 80° C. for 10 minutes. Different from the above-mentioned Examples and Comparative examples, no protective layer was provided on the upper portions of these photo-curable light-sensitive layers.

### (Photo-Curable Light-Sensitive Layer Prescription 4)

| | | |
|---|---|---|
| Polymer (Table 9) | 1.10 | parts |
| Pentaerythritol tetraacrylate | 0.50 | part |
| Organic boron salt compound (BC-6) | 0.20 | part |
| Trihaloalkyl-substituted compound (T-3) | 0.15 | part |
| Sensitizing dye (S-34) | 0.04 | part |
| Phthalocyanine Blue (coloring pigment) | 0.05 | part |
| N-nitrosophenylhydroxylamine aluminum salt | 0.02 | part |
| Dioxane | 20 | parts |
| Ethanol | 5 | parts |

TABLE 9

| | Polymer |
|---|---|
| Example 16 | SP-4 |
| Example 17 | SP-6 |
| Example 18 | Synthetic example 4 |
| Example 19 | Synthetic example 6 |
| Comparative | Comparative synthetic |
| example 9 | example 2 |

### (Exposure Test)

The obtained light-sensitive lithographic printing plate material was adhered to an aluminum plate with a thickness of 0.24 mm, and by using an image setter PT-R4000 (an image drawing device mounting a laser with 830 nm) for a thermal plate manufactured by DAINIPPON SCREEN MFG. CO., LTD., exposure was carried out by setting an exposure dose irradiated to the lithographic plate to 100 mJ/cm². The exposed light-sensitive lithographic printing plate material was treated by using a developing solution which comprises distilled water alone, and using an automatic developing device P-1310T manufactured by Mitsubishi Paper Mills Limited as a developing device at 30° C. for 15 seconds. In the same manner as in the previous Examples, evaluation of printability was carried out, and printing endurance, background stain and background stain after plate preservation were evaluated. The results are summarized in Table 10.

TABLE 10

| | Printing | Background | Background stain |
|---|---|---|---|
| | endurance | stain | after placing plate |
| Example 16 | Δ | ◯ | ◯ |
| Example 17 | ◯ | ◯ | ◯ |
| Example 18 | ◯ | ◯ | Δ |
| Example 19 | ◯ | ◯ | ◯ |
| Comparative | Δ | ◯ | X |
| example 9 | | | |

From the above-mentioned results, with regard to the background stain immediately after development, difference cannot be admitted between Examples 16 to 19 and Comparative example 9, but with regard to printing endurance and background stain after plate preservation, the obtained results show that Examples 16 to 19 are clearly excellent.

### UTILIZABILITY IN INDUSTRY

The light-sensitive lithographic printing plate material provided by the present invention has high sensitivity to laser which emits in the near infrared region (750 to 1100 nm) or in the wavelength region of 400 to 430 nm, and developable with water or an aqueous alkali solution having a pH of 12 or less, so that it is suitable not only for a printing plate for CTP utilizing the same but also for formation of a resist for preparing a printed wiring board, or a color filter, a fluorescent pattern, etc.

1. A light-sensitive lithographic printing plate material which comprises a support and a photo-curable light-sensitive layer formed thereon, and said photo-curable light-sensitive layer contains a polymer synthesized by using at least a compound represented by the following general formula I: 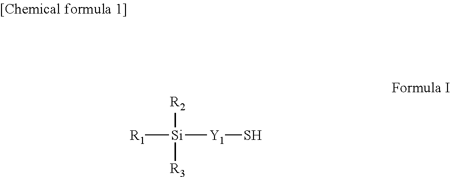
wherein R₁, R₂ and R₃ each independently represent an alkyl group or an alkoxy group each having 1 to 10 carbon atoms; provided that at least two of R₁, R₂ and R₃ represent alkoxy groups; and Y₁ represents an alkylene group having 1 to 10 carbon atoms,
and having a polymerizable double bond group, and at least one of a carboxyl group and a sulfonate group at a side chain.

2. The light-sensitive lithographic printing plate material according to claim 1, wherein the polymer is a polymer having a group represented by the following mentioned general formula II: 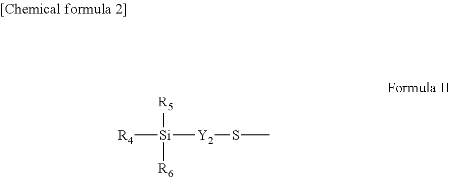
wherein R₄, R₅ and R₆ each independently represent a hydroxyl group, an alkyl group or an alkoxy group each having 1 to 10 carbon atoms; provided that at least two of R₄, R₅ and R₆ represent hydroxyl groups or alkoxy groups; and Y₂ represents an alkylene group having 1 to 10 carbon atoms,
at the end of a main chain, and having a polymerizable double bond group, and a carboxyl group or a sulfonate group at a side chain.

3. The light-sensitive lithographic printing plate material according to claim 1, wherein the polymer is a polymer in which a unit having a polyorganosiloxane structure, and a unit having a polymerizable double bond group, and a carboxyl group or a sulfonate group at a side chain are bonded through a sulfur atom.

4. The light-sensitive lithographic printing plate material according to claim 1, wherein the polymerizable double bond group possessed by the polymer at the side chain is a vinyl group bonded to a phenyl group.

5. The light-sensitive lithographic printing plate material according to claim 1, wherein the photo-curable light-sensitive layer on the support further contains a photopolymerization initiator.

6. The light-sensitive lithographic printing plate material according to claim 5, wherein the photo-curable light-sensitive layer on the support further contains a compound which sensitizes the photopolymerization initiator to a light of 400 to 430 nm or 750 to 1100 nm.

7. The light-sensitive lithographic printing plate material according to claim 1, wherein the polymer is obtained by copolymerizing a carboxyl group-containing monomer or a sulfonate group-containing monomer in an amount of 20% by weight to 70% by weight based on the total monomer.
